(19) United States
(12) Patent Application Publication
(10) Pub. No.: US 2026/0107431 A1
(43) Pub. Date: Apr. 16, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Ming-Heng TSAI, Taipei City (TW); Ta-Chun LIN, Hsinchu (TW); Hong-Chih CHEN, Changhua County (TW); Chun-Sheng LIANG, Changhua County (TW)

(73) Assignee: TAIWAN SEMICONDUCTOR MANUFACTURING COMPANY, LTD., Hsinchu (TW)

(21) Appl. No.: 18/912,378

(22) Filed: Oct. 10, 2024

(51) Int. Cl. H10B 10/00; H01L 21/027; H01L 27/02; H01L 27/092; H01L 29/06; H01L 29/417; H01L 29/423; H01L 29/66; H01L 29/775; H01L 29/786

(52) U.S. Cl. CPC H10B 10/125; H10D 30/014; H10D 30/6729; H10D 62/121; H10D 64/017; H10D 84/85; H10D 89/10; H10P 76/2043; H10D 30/43; H10D 30/6735; H10D 30/6757

(57) ABSTRACT

A semiconductor device comprises a first transistor and a second transistor vertically above first transistor. The first transistor comprises a plurality of first semiconductor layers spaced apart from each other along a first direction and a first gate structure around the plurality of first semiconductor layers. One of the plurality of first semiconductor layers has a first width along a second direction perpendicular to the first direction. The second transistor comprises a plurality of second semiconductor layers spaced apart from each other along the first direction and a second gate structure around the plurality of second semiconductor layers. One of the plurality of second semiconductor layers has a second width along the second direction, and a ratio of the second width to the first width or a ratio of the first width to the second width is in a range from about 0.25 to about 0.8.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure. In the present disclosure, a complementary FET (CFET) is provided, and its manufacturing method will be disclosed in the following discussion.

FIGS. 2A, 3A, 4A, 5A, 6A, 7A, 8A, 9A, 10A, 10C, 11A, 12A, 13A, 14A, 15A, 16A, 17A, 18A, 19A, 20A, 21A and 22A are cross-sectional views of the CFET same as the cross-sectional view along line A-A of FIG. 1 at various stages of fabrication according to various embodiments of the present disclosure.

FIGS. 2B, 3B, 4B, 5B, 6B, 7B, 8B, 9B, 10B, 11B, 12B, 13B, 14B, 15B, 16B, 17B, 18B, 19B, 20B, 21B and 22B are cross-sectional views of the CFET same as the cross-sectional view along line B-B of FIG. 1 at various stages of fabrication according to various embodiments of the present disclosure.

FIGS. 8C, 18C, 21C and 22C are cross-sectional views of the CFET same as the cross-sectional view along line C-C of FIG. 1 at various stages of fabrication according to various embodiments of the present disclosure.

FIG. 22D is a simplified schematic top view of a first cell layout diagram of a semiconductor device in accordance with some embodiments of the present disclosure.

FIG. 22E is a cross-sectional view along line X2-X2′ of FIG. 22D in accordance with some embodiments.

FIG. 23 is a simplified schematic top view of a second cell layout diagram of a semiconductor device in accordance with some embodiments of the present disclosure.

FIG. 24 is a cross-sectional view of the CFET along line B-B of FIG. 1, which is similar to the cross-sectional view with respect to FIG. 22C, except for the substrate portion having the width different from both of the width of the semiconductor layer and the width of the semiconductor layer.

FIG. 25 is a cross-sectional view of the CFET along line B-B of FIG. 1 similar to the cross-sectional view with respect to FIG. 22C, except for the width of the semiconductor layer being greater than the width of the semiconductor layer.

FIG. 26A is a circuit diagram of a six transistor (6T) SRAM cell.

FIG. 26B shows an exemplary cross-sectional view of the first inverter in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The present disclosure is related to integrated circuit (IC) structures and methods of forming the same. More particularly, some embodiments of the present disclosure are related to gate-all-around (GAA) devices. A GAA device includes a device that has its gate structure, or portions thereof, formed on four-sides of a channel region (e.g., surrounding a portion of a channel region). The channel region of a GAA device may include nanosheet channels, bar-shaped channels, and/or other suitable channel configurations. In some embodiments, the channel region of a GAA device may have multiple horizontal nanosheets or horizontal bars vertically spaced, making the GAA device a stacked horizontal GAA (S-HGAA) device. The GAA devices presented herein include a p-type metal-oxide-semiconductor GAA device and an n-type metal-oxide-semiconductor GAA device stack together. Further, the GAA devices may have one or more channel regions (e.g., nanosheets) associated with a single, contiguous gate structure, or multiple gate structures. One of ordinary skill may recognize other examples of semiconductor devices that may benefit from aspects of the present disclosure. In some embodiments, the nanosheets can be interchangeably referred to as nanowires, nanoslabs, nanorings, or nanostructures having nano-scale size (e.g., a few nanometers), depending on their geometry. In addition, the embodiments of the disclosure may also be applied, however, to a variety of metal oxide semiconductor transistors (e.g., complementary-field effect transistor (CFET) and fin field effect transistor (FinFET)).

Some embodiments of the present disclosure provide a complementary-field effect transistor (CFET) with a gate-all-around configuration which includes a first gate-all-around (GAA) device with a first conductivity-type and a second gate-all-around (GAA) device with a second conductivity-type different from the first conductivity-type. The first GAA device and the second GAA device form a stacked horizontal GAA (S-HGAA) device. The first GAA device can include nanosheets with a width different from a width of nanosheets of the second GAA device to modulate direct current (DC) for the first GAA device and the second GAA device. Therefore, Logic Design Technology Co-Optimization (DTCO) can be enabled and read/write margin for static random access memory (SRAM) can be improved.

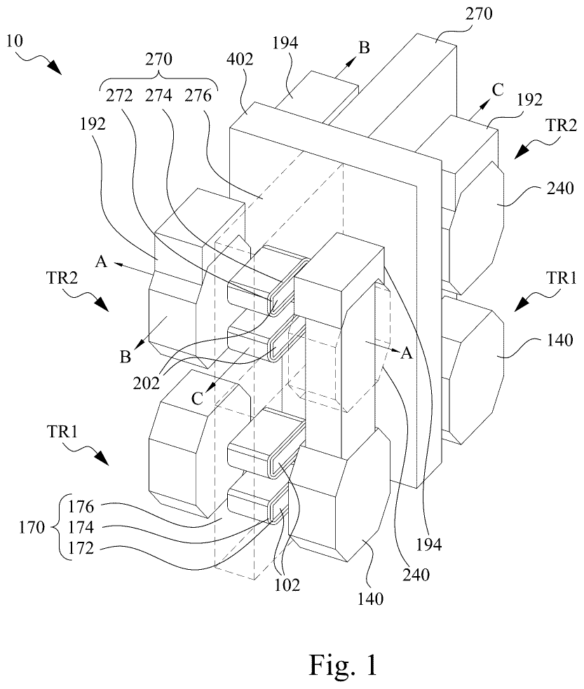

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, first transistors TR1 are disposed over a substrate (not shown), and second transistors TR2 are disposed on the respective first transistors TR1. In some embodiments, the first transistors TR1 and the second transistors TR2 each may be field effect transistor (FET) and may both include gate-all-around (GAA) configuration, and thus the first transistors TR1 and the second transistors TR2 can also be referred to as GAA FETs. Each of the first transistors TR1 includes first semiconductor layers 102 vertically stacked one above another, a first metal gate structure 170 wrapping around each of the first semiconductor layers 102, and first source/drain epitaxy structures 140 on opposite ends of each of the first semiconductor layers 102. Similarly, each of the second transistors TR2 includes second semiconductor layers 202 vertically stacked one above another, a second metal gate structure 270 wrapping around each of the second semiconductor layers 202, and second source/drain epitaxy structures 240 on opposite ends of each of the second semiconductor layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, each of the first transistors TR1 has a first conductivity type (e.g., p-type) and each of the second transistors TR2 has a second conductivity type (e.g., n-type) different from the first conductivity type. In some embodiments, the first transistors TR1 can be referred to as PFETs, and the second transistors TR2 can be referred to as NFETs. In some embodiments, the interfacial layer 172 and the interfacial layer 272 can include different thicknesses and/or different materials, and the gate dielectric layer 174 and the gate dielectric layer 274 can include different thicknesses and/or different materials. FIG. 1 assumes an orthogonal XYZ coordinate system.

A dielectric structure 402 is disposed between two adjacent first transistors TR1, so as to electrically isolate the two adjacent first transistors TR1. Similarly, the dielectric structure 402 is disposed between two adjacent second transistors TR2, so as to electrically isolate the two adjacent second transistors TR2. The CFET 10 further includes source/drain contacts 192 and 194. The source/drain contacts 192 and 194 are disposed over the respective second source/drain epitaxy structures 240. In some embodiments, the source/drain contact 192 is in contact with top surface of the corresponding second source/drain epitaxy structure 240.

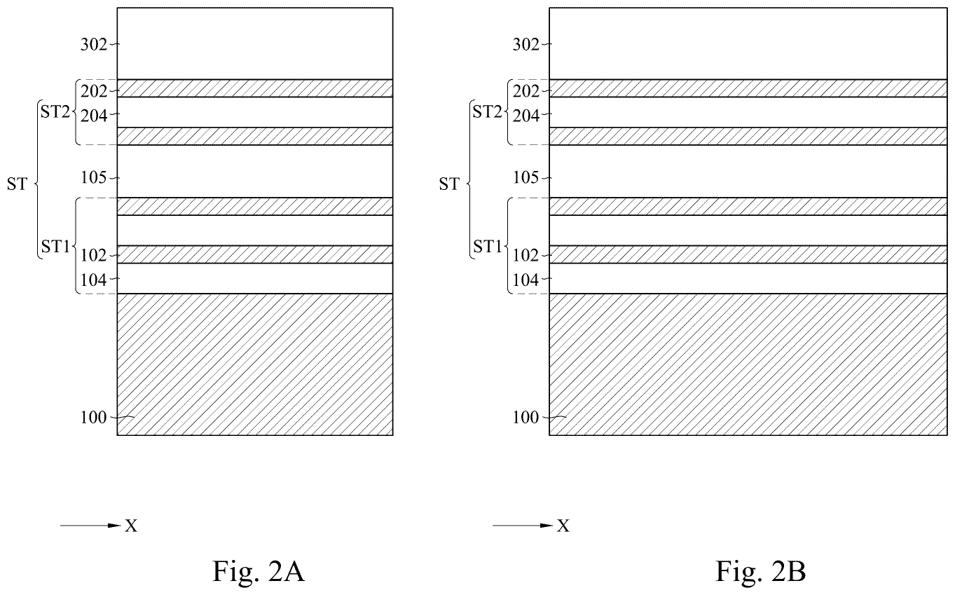

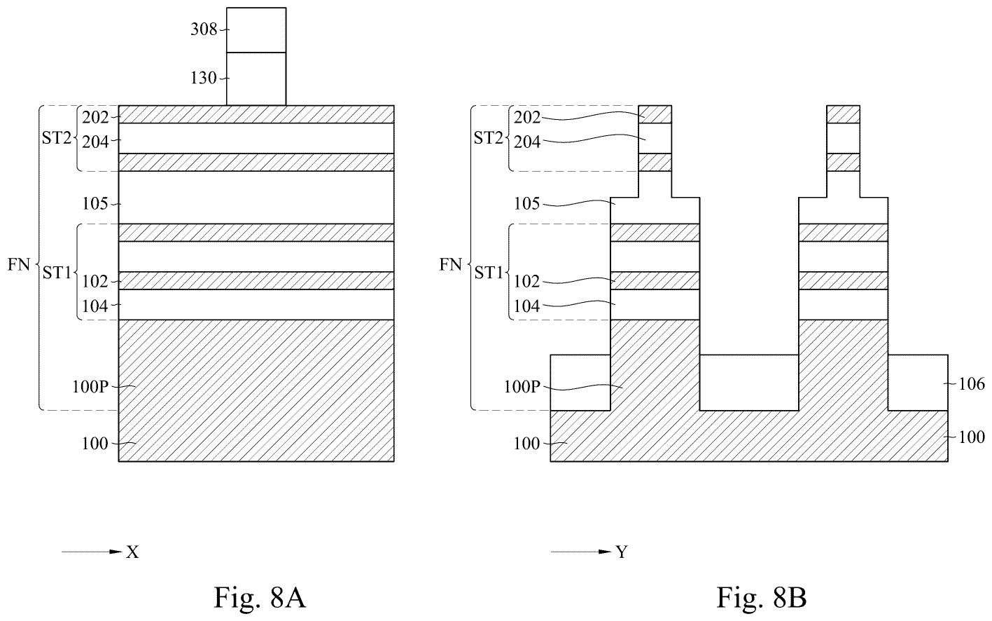

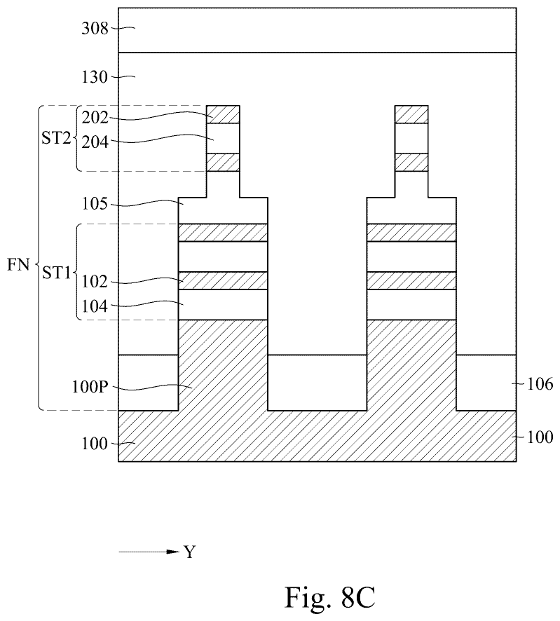

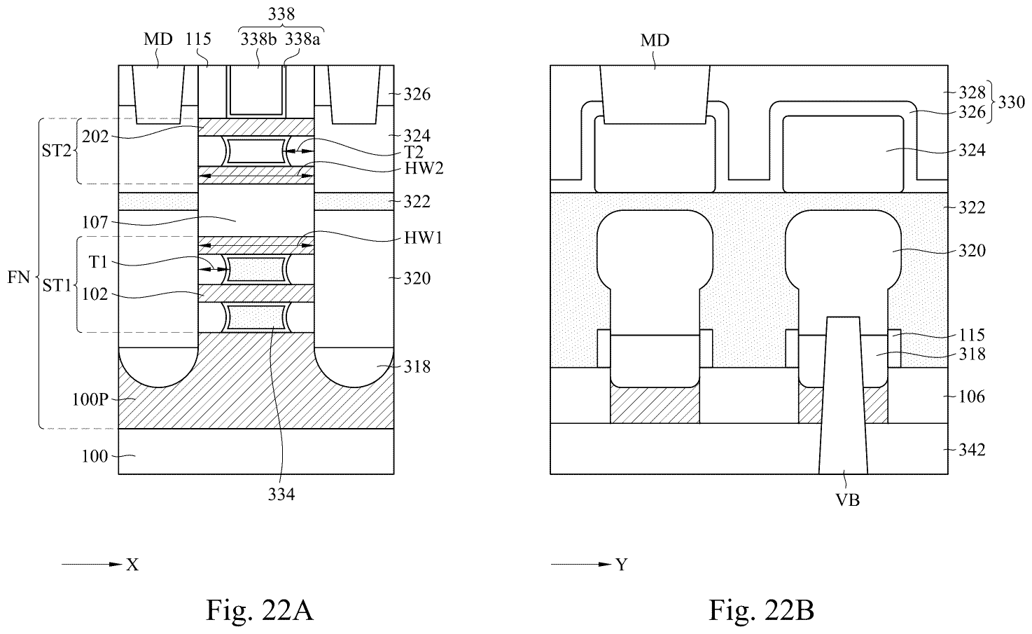

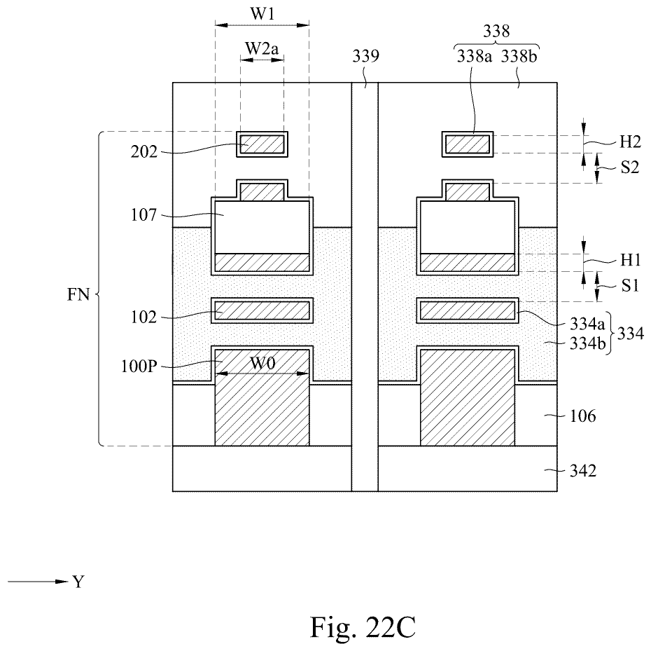

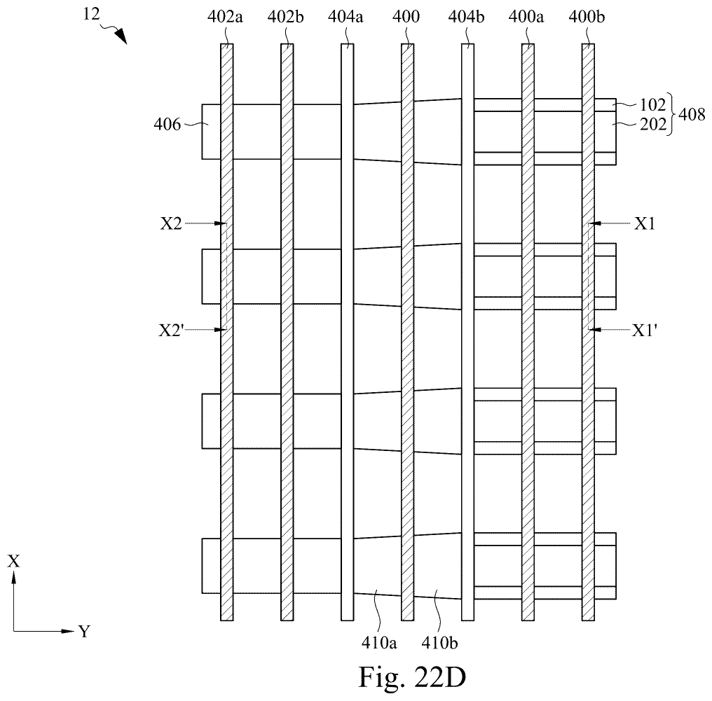

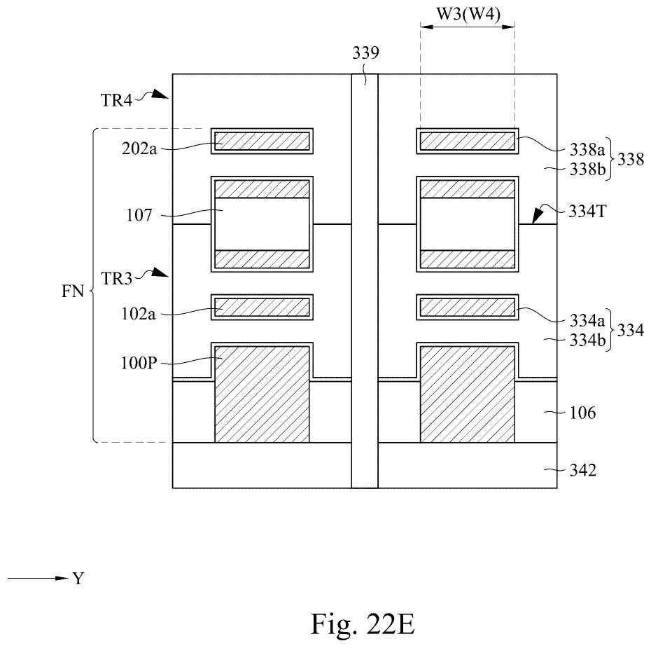

FIGS. 2A to 22E illustrate a method in various stages of forming a semiconductor device in accordance with some embodiments of the present disclosure. FIGS. 2A, 3A, 4A, 5A, 6A, 7A, 8A, 9A, 10A, 10C, 11A, 12A, 13A, 14A, 15A, 16A, 17A, 18A, 19A, 20A, 21A and 22A are cross-sectional views of the CFET same as the cross-sectional view along line A-A of FIG. 1 at various stages of fabrication according to various embodiments of the present disclosure. FIGS. 2B, 3B, 4B, 5B, 6B, 7B, 8B, 9B, 10B, 11B, 12B, 13B, 14B, 15B, 16B, 17B, 18B, 19B, 20B, 21B and 22B are cross-sectional views of the CFET same as the cross-sectional view along line B-B of FIG. 1 at various stages of fabrication according to various embodiments of the present disclosure. FIGS. 8C, 18C, 21C and 22C are cross-sectional views of the CFET same as the cross-sectional view along line C-C of FIG. 1 at various stages of fabrication according to various embodiments of the present disclosure. FIG. 22D is a simplified schematic top view of a first cell layout diagram of a semiconductor device 12 in accordance with some embodiments of the present disclosure. FIG. 22E is a cross-sectional view along line X2-X2′ of FIG. 22D in accordance with some embodiments. FIGS. 2A to 22E are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 22E may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, in which the semiconductor layer 105 may be thicker than the semiconductor layers 104 and 204 along the vertical direction. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers. The illustrated number of semiconductor layers 102 and 104 and semiconductor layers 202 and 204 is merely an example and other number may be used. For example, the number of the semiconductor layers 102, 104, 202, 204 can be 1, 2, 3, 4 or more than 4.

As also shown in the example of FIGS. 2A and 2B, a hard mask (HM) layer 302 may be formed over the semiconductor stack ST. In some embodiments, the HM layer 302 includes an oxide layer (e.g., a pad oxide layer that may include SiO₂) and nitride layer (e.g., a pad nitride layer that may include Si₃N₄) formed over the oxide layer. In some examples, the HM layer 302 includes thermally grown oxide, chemical vapor deposition (CVD)-deposited oxide, and/or atomic layer deposition (ALD)-deposited oxide. In some embodiments, the HM layer 302 includes a nitride layer deposited by CVD and/or other suitable technique. The HM layer 302 may be used to protect portions of the substrate 100 and/or semiconductor stack ST and/or used to define a pattern (e.g., fin elements) as discussed below.

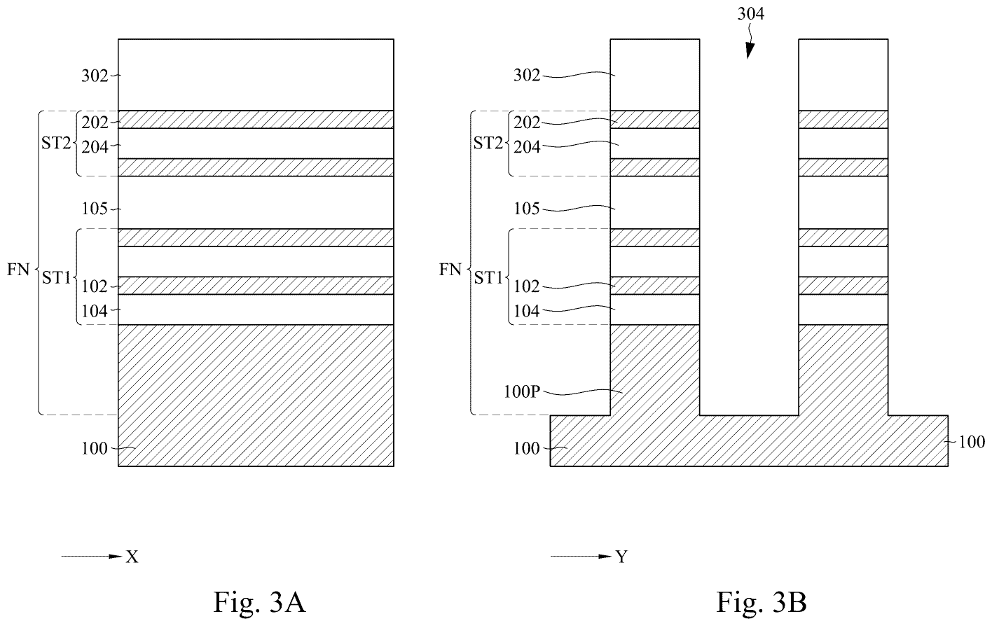

Reference is made to FIGS. 3A and 3B. A plurality of fin structures FN is formed extending from the substrate 100. In various embodiments, each of the fin structures FN includes a substrate portion 100P formed from the substrate 100, portions of each of the semiconductor layers 102, 104 from the first stack ST1, the semiconductor layer 105, portions of each of the semiconductor layers 202, 204 from the second stack ST2, and an HM layer portion from the HM layer 302. In some embodiments, the substrate portion 100P can also be referred to as a mesa portion.

The fin structures FN may be fabricated using suitable processes including photolithography and etch processes. The photolithography process may include forming a photoresist layer over the substrate 100 (e.g., over the HM layer 302 of FIGS. 2A-2B), exposing the photoresist to a pattern, performing post-exposure bake processes, and developing the photoresist to form a masking element including the photoresist. In some embodiments, pattering the photoresist to form the masking element may be performed using an electron beam (e-beam) lithography process. The masking element may then be used to protect regions of the substrate 100, and layers formed thereupon, while an etch process forms trenches 304 in unprotected regions through the HM layer 302, through the second stack ST2, the first stack ST1, and into the substrate 100, thereby leaving the plurality of extending fin structures FN. The trenches 304 may be etched using a dry etch (e.g., reactive ion etching), a wet etch, and/or combination thereof.

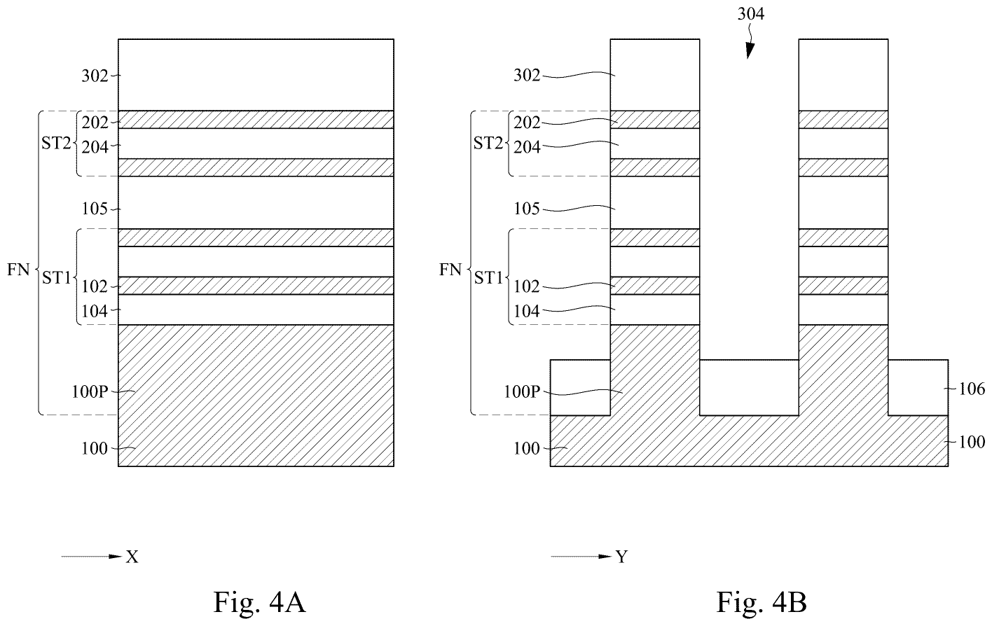

Reference is made to FIGS. 4A-4B. After the fin structures FN are formed, isolation structures 106 are formed over the substrate 100 and laterally surrounding the fin structures FN. In some embodiments, the isolation structures 106 may be in contact with sidewalls of the substrate portion 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

Afterwards, in some embodiments, a bottom antireflective coating (BARC) layer 306 can be formed over the fin structures FN, including filling in the trenches 304. The BARC layer 306 may include spin-on glass, bottom anti-reflective coating (BARC), silicon oxide, silicon nitride, oxynitride, silicon carbide, and/or other suitable materials. The BARC layer 306 may include an organic BARC or an inorganic BARC layer. In some embodiments, the BARC layer 306 includes a material which is different from a material of the hard mask to achieve etching selectivity subsequent etches. The BARC layer 306 may be deposited by spin-on coating, CVD, physical vapor deposition (PVD), ALD, or other suitable techniques. In an embodiment, the BARC layer 306 fully fills in the trenches 304.

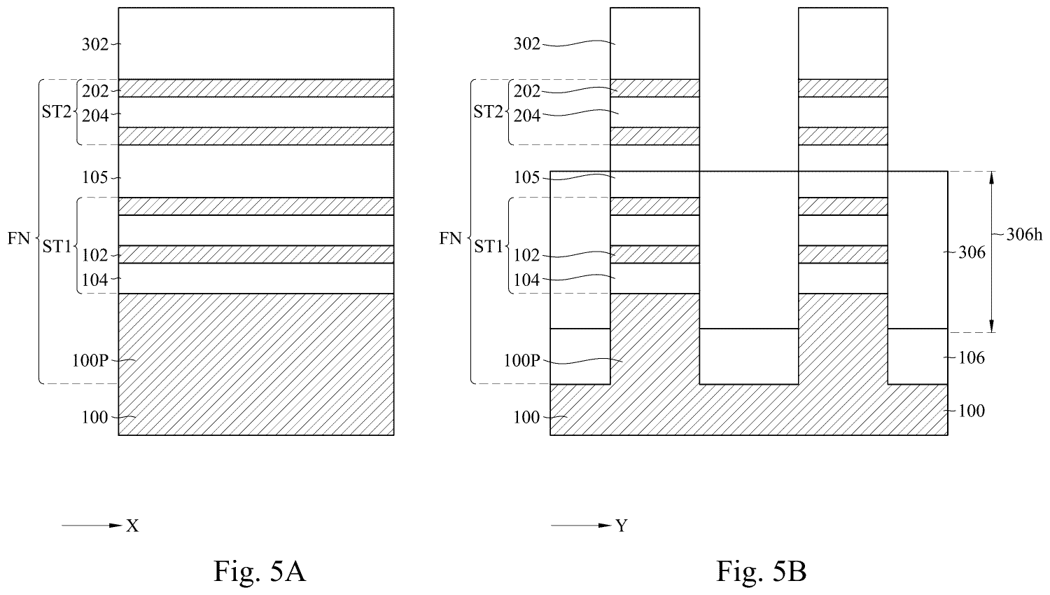

Then, the BARC layer 306 can be recessed using, such as an etch back process. The resulting structure is shown in FIGS. 5A and 5B. The etch back process may include a wet etch, a dry etch, and/or a combination thereof. For example, dry etching processes may include a biased plasma etching process that uses etchant gasses including CF₄, NF₃, SF₆, and/or He. In some embodiments, the etch process is chosen to selectively etch the BARC layer 306 without substantially etching the HM layer 302 and the fin structure FN. Thus, the BARC layer 306 is recessed with a self-alignment nature, which relaxes process constrains. The recessed BARC layer 306 thereafter has a height 306h. After recessing the BARC layer 306, the HM layer 302 and a portion of the fin structures FN are uncovered by the BARC layer 306, as shown in FIG. 5B. For example, the BARC layer 306 can cover a lower sidewall or a lower portion 105L of the semiconductor layer 105 while leaving an upper sidewall or an upper portion 105U of the semiconductor layer 105 uncovered or exposing the upper sidewall or an upper portion 105U of the semiconductor layer 105. In particular, the BARC layer 306 can cover the first stack ST1 while leaving the second stack ST2 and the HM layer 302 uncovered. Therefore, the BARC layer 306 can protect a lower portion the semiconductor layer 105 and the first stack ST1 from a subsequent trimming operation. Thus, the BARC layer 306 can also be referred to as a protective layer.

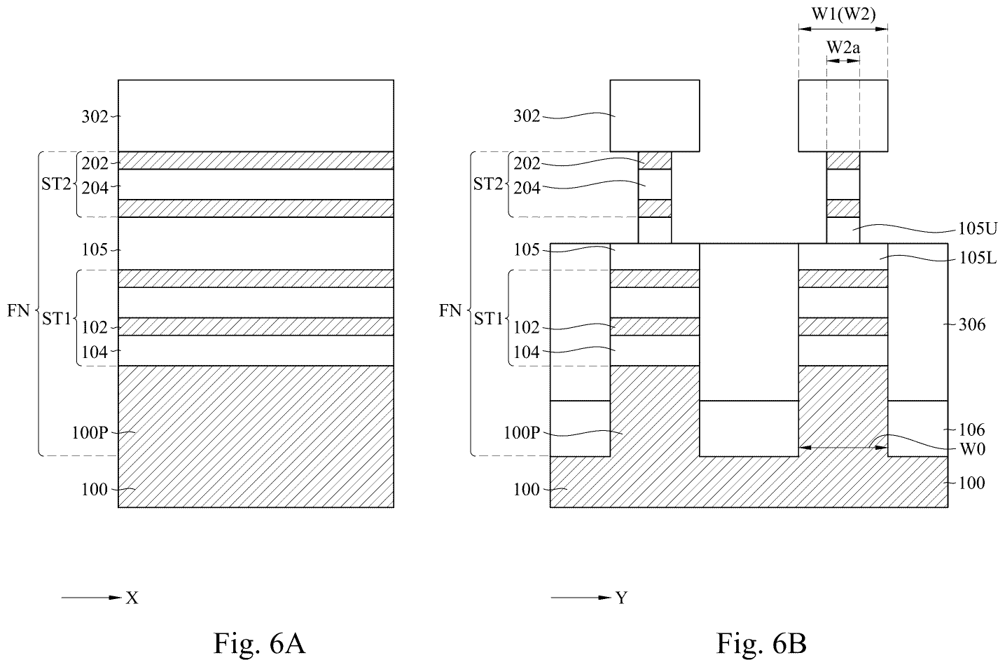

Reference is made to FIGS. 6A and 6B. A trimming operation is then performed to reduce a width of the second stack ST2 of the fin structures FN. The trimming operation uses any suitable etching process such as dry etching, wet etching, and/or RIE. In an embodiment, the semiconductor layers 202 in the fin structures FN are trimmed to have about the same dimensions (e.g., the width) as the semiconductor layers 204 in the second stack ST2 of fin structures FN. In some embodiments, after performing the trimming operation, the semiconductor layers 202, 204 has a width W2a along the Y direction different from a width W2 of the semiconductor layers 202, 204 along the Y direction before the trimming operation, and different from a width W1 of the semiconductor layers 102, 104. For example, after performing the trimming operation, the semiconductor layers 202, 204 has the width W2a smaller than the width W2 of the semiconductor layers 202, 204 before the trimming operation, and smaller than the width W1 of the semiconductor layers 102, 104, which would be discussed in greater detail below. In some embodiments, the trimming operation is performed to trim the upper portion 105U of the semiconductor layer 105 without trimming the lower portion 105L of the semiconductor layer 105. In other words, the trimming operation is performed to trim the upper portion 105U of the semiconductor layer 105 such that the upper portion 105U of the semiconductor layer 105 is narrower than a lower portion 105L of the semiconductor layer 105 after the trimming operation is complete.

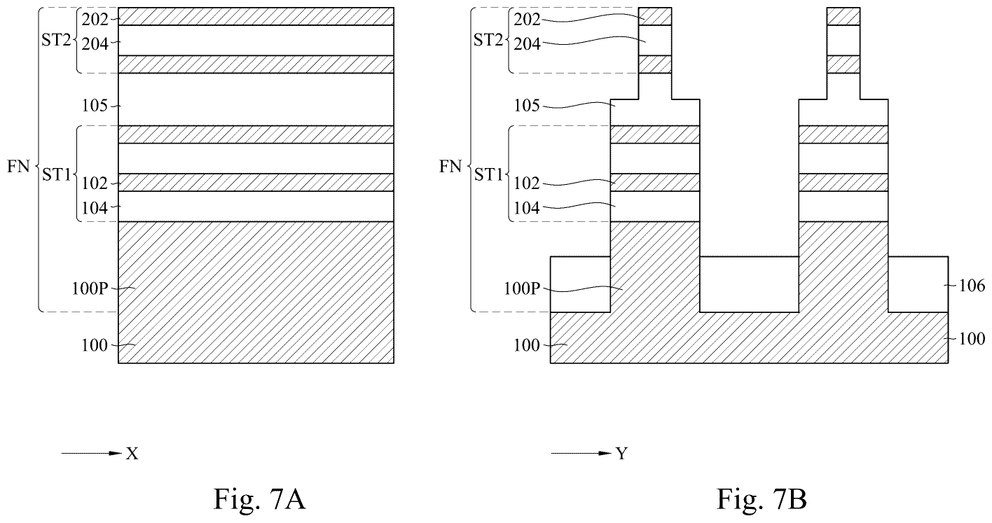

Reference is made to FIGS. 7A and 7B. In some embodiments, the HM layer 302 and the BARC layer 306 can be removed such as using an etch process including a wet etch, a dry etch, and/or a combination thereof. For example, a wet etching solution may include NH₄OH, KOH, HF, TMAH, and/or other suitable wet etching solutions, and/or combinations thereof. In some embodiments, the etch process is chosen to selectively etch the HM layer 302 and the BARC layer 306 without substantially etching the fin structures FN and the isolation structures 106. Thus, the BARC layer 306 is removed with a self-alignment nature, which relaxes process constrains.

Reference is made to FIGS. 8A, 8B, and 8C. Dummy gate structures 130 are formed over the substrate 100 and crossing the fin structures FN (see FIG. 8C). In some embodiments, each of the dummy gate structures 130 includes a dummy gate dielectric and a dummy gate electrode over the dummy gate dielectric. The dummy gate dielectric may be, for example, silicon oxide, silicon nitride, a combination thereof, or the like, and may be deposited or thermally grown according to acceptable techniques. The dummy gate electrode may be a conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode and the dummy gate dielectric may be formed by, for example, depositing a dummy dielectric layer and a dummy gate layer over the substrate 100, forming a patterned mask 308 over the dummy gate layer, and then performing an etching process to the dummy gate dielectric and the dummy gate electrode by using the patterned mask 308 as an etch mask. In some embodiments, the dummy gate electrode may be deposited by physical vapor deposition (PVD), chemical vapor deposition (CVD), sputter deposition, or other techniques for depositing the selected material. In some embodiments, the dummy gate dielectric may be formed by thermal oxidation.

In some embodiments, the patterned mask 308 includes a first hard mask and a second hard mask over the first hard mask. The first hard mask and the second hard mask may be made of different materials. In some embodiments, the second hard mask may be formed of silicon nitride, and the first hard mask may be formed of silicon oxide. The patterned mask 308 can then be removed by suitable etching method.

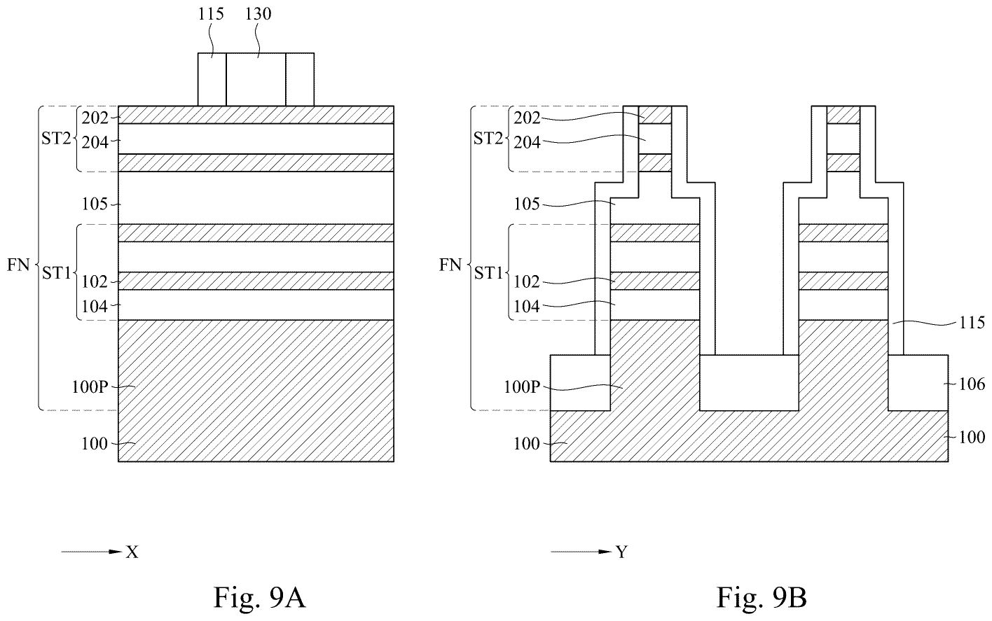

Reference is made to FIGS. 9A and 9B. Spacers 115 are formed on opposite sidewalls of each of the dummy gate structures 130 (see FIG. 9A), and on opposite sidewalls of the fin structures FN (see FIG. 9B). In some embodiments, portions of the spacers 115 on opposite sidewalls of each of the dummy gate structures 130 can be referred to as gate spacers, and portions of the spacers 115 on opposite sidewalls of the fin structures FN can be referred to as fin spacers. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate 100, the fin structures FN and the isolation structures 106, and then performing an anisotropic etching process to remove horizontal portions of the spacer layer, such that vertical portions of the spacer layer remain on sidewalls of the dummy gate structures 130 and on sidewalls of the fin structures FN. In some embodiments, the remaining vertical portions of the spacer layer can be referred to as the spacers 115. The spacer layer may be deposited using techniques such CVD, ALD, or the like.

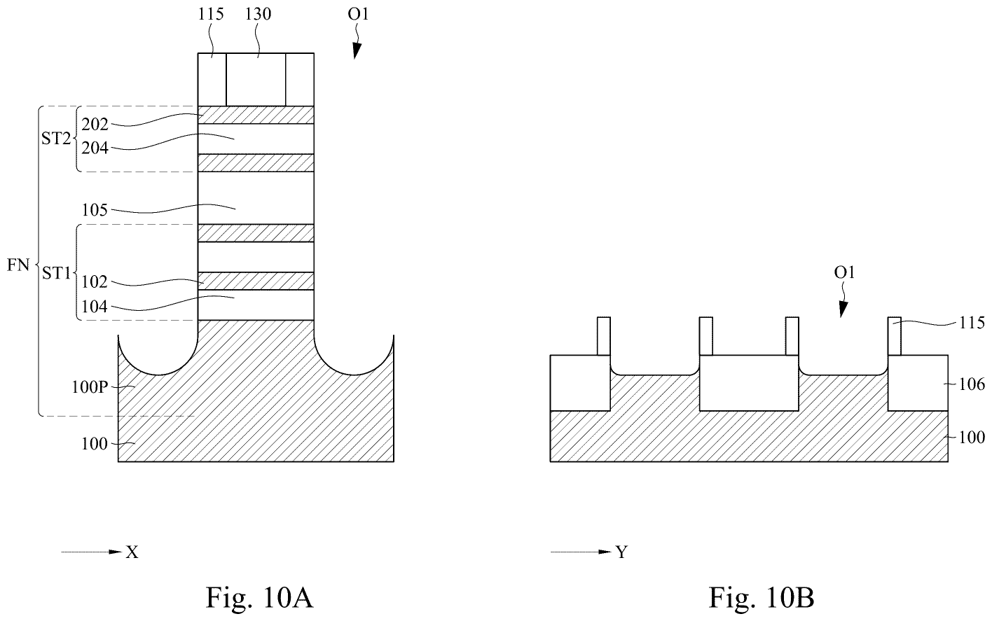

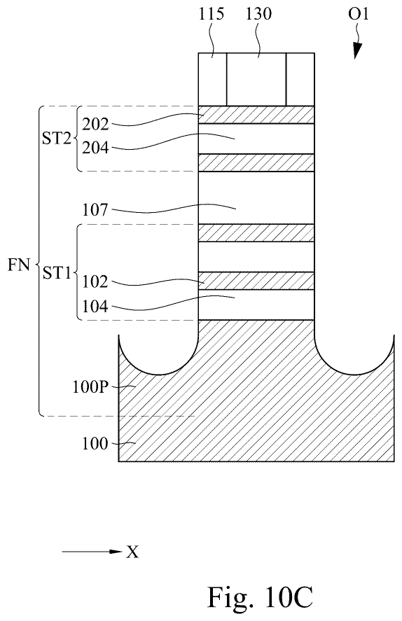

Reference is made to FIGS. 10A and 10B. An etching process is performed to remove portions of the fin structures FN (or the semiconductor stack ST) by using the dummy gate structures 130 and the spacers 115 as etch mask, so as to form source/drain openings O1 in the fin structures FN. In some embodiments, the etching process may be wet etch, dry etch, or combinations thereof. In some embodiments, the bottommost ends of the source/drain openings O1 may be lower than the bottommost semiconductor layer 104.

Reference is made to FIG. 10C. The semiconductor layer 105 is then replaced with a middle dielectric isolation (MDI) structure 107. For example, a suitable etch process is performed to remove the semiconductor layer 105 to form a gap followed by refilling the gap with a dielectric material and etching back the dielectric material outside the gap. In some embodiments, the dielectric material can include silicon nitride, silicon oxynitride, or the like, to provide isolation for semiconductor layers 102 and 202. In other words, the MDI structure 107 is used to separate the bottom transistor (the first transistor TR1) and the top transistor (the second transistor TR2).

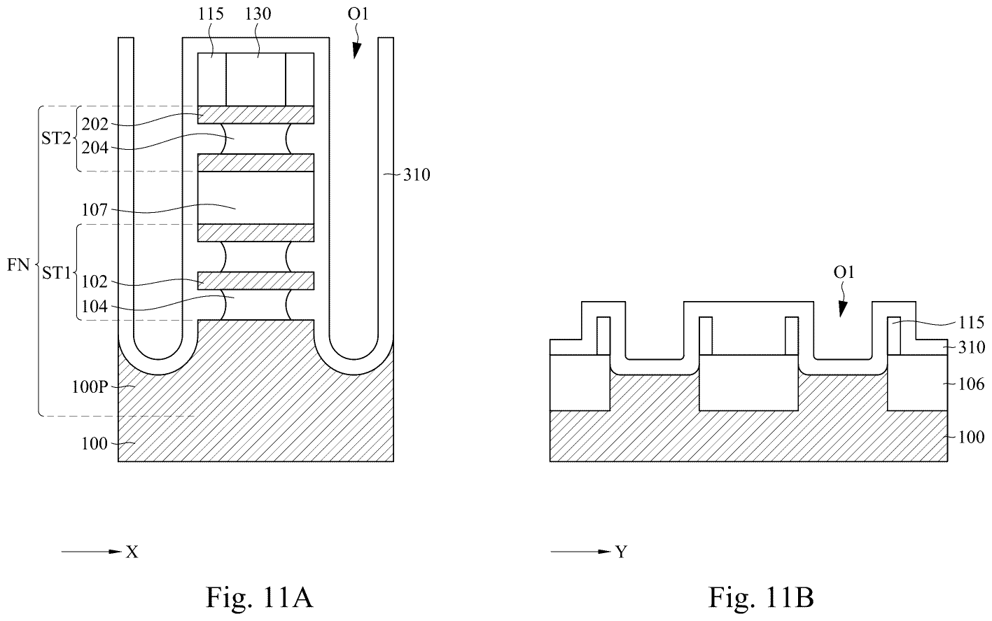

Reference is made to FIGS. 11A and 11B. After the source/drain openings O1 are formed, the semiconductor layers 104, 105, and 204 are laterally etched to form sidewall recesses. In some embodiments, the sidewalls of the semiconductor layers 104, 105, and 204 may be etched using isotropic etching processes, such as wet etching or the like. In some embodiments where the semiconductor layers 104, 105, and 204 include, e.g., SiGe, and the semiconductor layers 102 and 202 include, e.g., Si, an etch process with tetramethylammonium hydroxide (TMAH), ammonium hydroxide (NH₄OH), or the like may be used to etch sidewalls of the semiconductor layers 104, 105, and 204.

An inner spacer material 310 is blanket formed over the recessed substrate 100, filling the sidewall recesses, formed over the source/drain openings O1, along sidewalls of the spacers 115, over the dummy gate structure 130 and over the isolation structures 106. The inner spacer material 310 may be deposited by a conformal deposition process, such as CVD, ALD, or the like. The inner spacer material 310 may include a material such as SiN, SiOCN, SiCN, SIOC, although any suitable material, such as low-dielectric constant (low-k) materials having a k-value less than about 3.5, may be utilized.

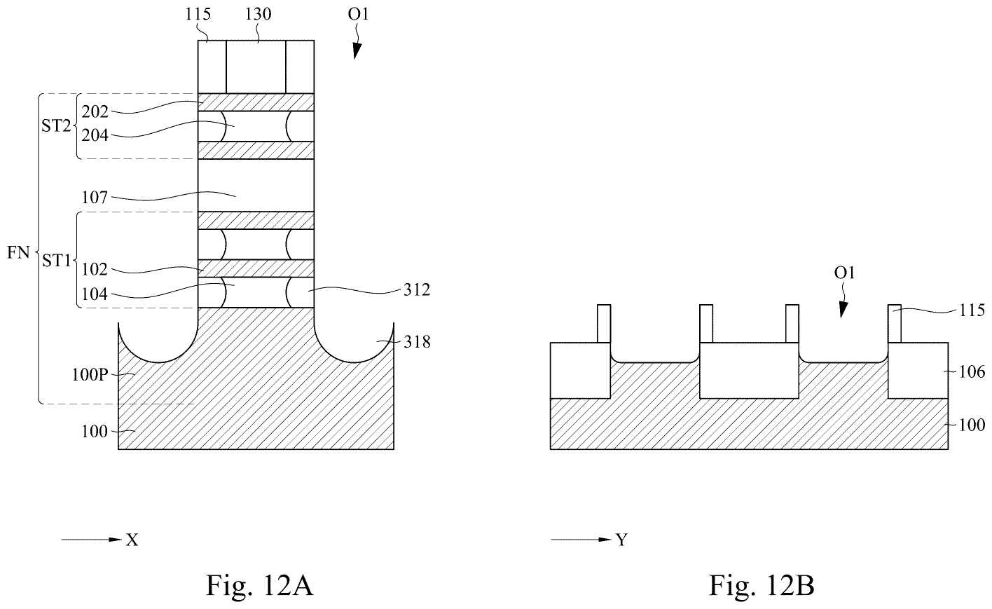

Reference is made to FIGS. 12A and 12B. Then, an anisotropic etching can be performed to remove portions of the inner spacer layer outside the sidewall recesses, leaving the remaining portions of the inner spacer layer in the sidewall recesses as the inner spacers 312.

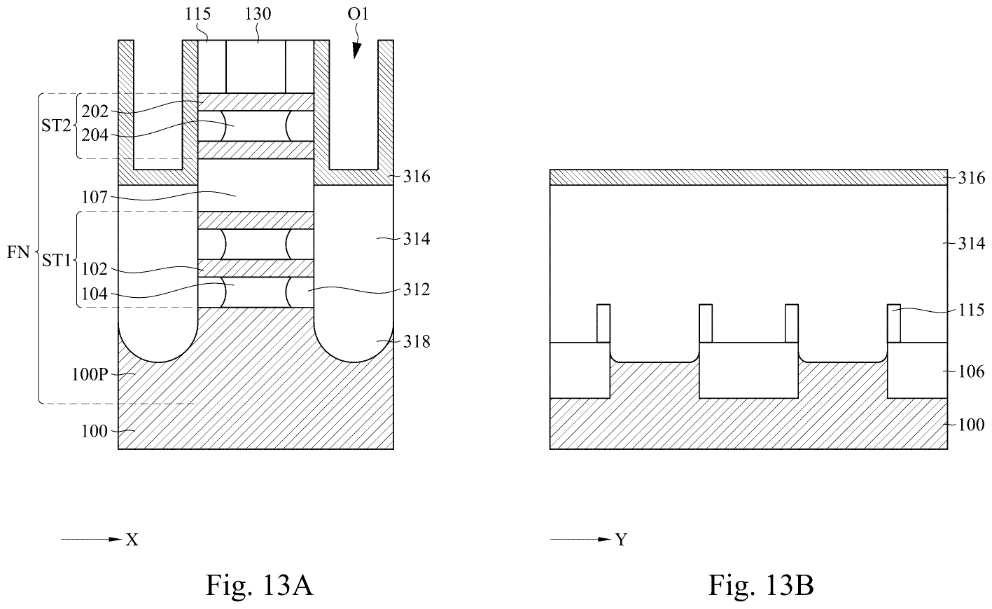

Referring to FIGS. 13A and 13B, dummy materials 314 and dielectric layers 316 are formed in the source/drain openings O1. The dummy materials 314 are formed of fluorine-containing polymer and its molecular structure includes silicon (Si), carbon (C), nitrogen (N), or fluorine (F). In one example, the dummy materials 314 include fluorinated silicone or fluorinated polysilane. Formation of the dummy materials 314 may include depositing the dummy materials 314 using CVD, flowable CVD (FCVD), or spin-on coating followed by an etch back process. In some embodiments, top surfaces of the dummy materials 314 are lower than the dummy gate structure 130 and the spacers 115. The dummy materials 314 can be in lower parts of the source/drain openings O1 to cover a bottom surface of the substrate 100 and the sidewalls of the semiconductor layer 102 (which are used for the p-type FET (PFET) of the CFET, such as the first transistors TR1 of the CFET 10 shown in FIG. 1) and the inner spacers 312 (which are between the semiconductor layers 102). After the formation of the dummy materials 314, the dielectric layers 316 are formed over the dummy materials 314 and on the sidewalls of the semiconductor layers 202 (which are used for the n-type FET (NFET) of the CFET, such as the second transistors TR2 of the CFET 10 shown in FIG. 1), the spacers 115, and the inner spacers 312 (which are between the semiconductor layers 202). The dielectric layers 316 may include aluminum oxide (Al₂O₃). Formation of the dielectric layers 316 may include depositing the dummy materials 314 using CVD, flowable CVD (FCVD), or spin-on coatings.

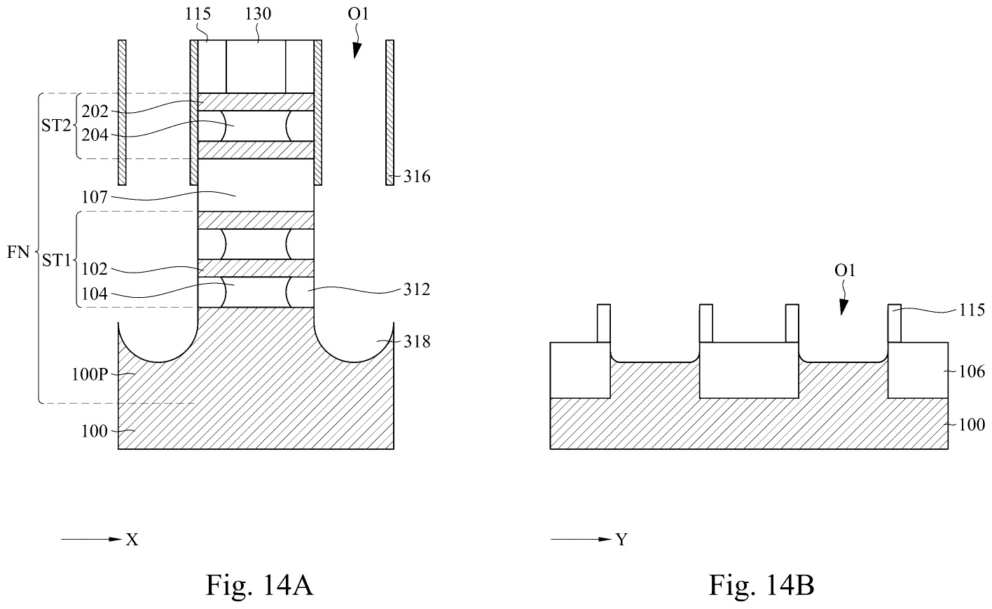

Referring to FIGS. 14A and 14B, the dummy materials 314 are removed via a selective etching process. The selective etching process is performed that selectively etches the dummy materials 314 below the dielectric layers 316 through the source/drain openings O1, with minimal (or no) etching of the semiconductor layers 102, the substrate 100, and the inner spacers 312. The selective etching process is a dry etching process, a wet etching process, other suitable etching process, or combinations thereof.

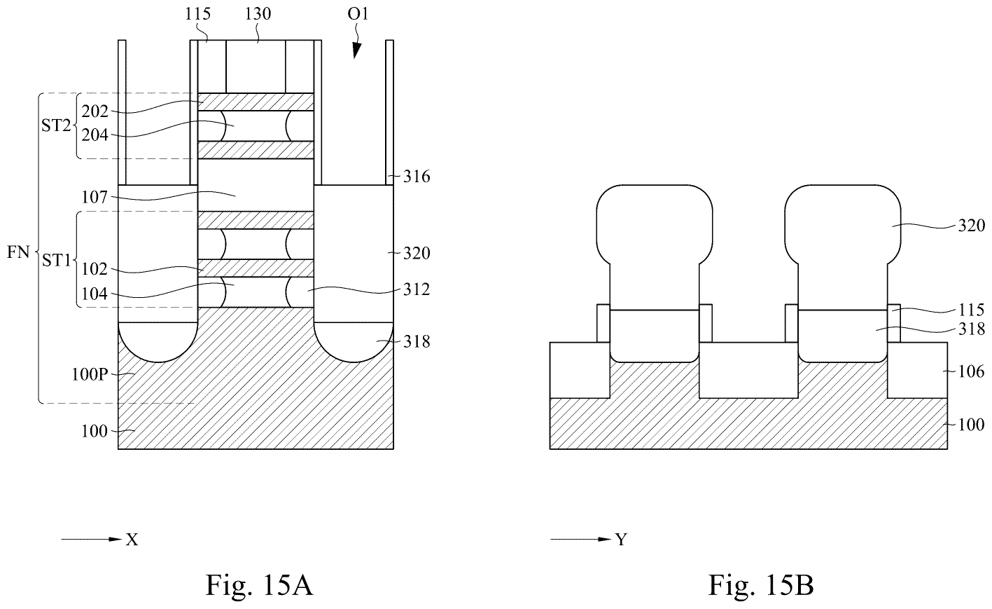

Referring to FIGS. 15A and 15B, after the removal of the dummy materials 314, an insulator layer 318 is optionally formed in the source/drain openings O1. The insulator layer 318 formed in the source/drain openings O1 can reduce the leakage current and can reduce the capacitance of the CFET 10. The insulator layer 318 may be formed of a dielectric material, and may be deposited by any suitable method, such as PVD, CVD, plasma-enhanced CVD (PECVD), or FCVD. Dielectric materials of the insulator layer 318 may include SiN, SiO₂, SiON, SiCN, SiCON, SiCO, high-k material (such as HfO, AlO) or multiple layers thereof.

In some embodiments, first source/drain epitaxy structures 320 are then formed in the source/drain openings O1, respectively. The first source/drain epitaxy structures 320 may be formed by suitable deposition process, such as a selective epitaxial growth (SEG) process. In some embodiments, the SEG process may selectively grow a semiconductor material on exposed semiconductor surfaces, such as the exposed surfaces of the semiconductor layers 102. In some embodiments, an implantation process may be performed to the first source/drain epitaxy structures 320. For example, the implantation process may include n-type dopants, such as phosphorus (P), arsenic (As), or antimony (Sb), or the like, such that the first source/drain epitaxy structures 320 are n-type epitaxy structures. One or more epitaxy processes may be employed to grow the first source/drain epitaxy structures 320. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The first source/drain epitaxy structures 320 are grown from the semiconductor layer 102 rather than the semiconductor layers 202 due to the dielectric layers 316 cover the sidewalls of the semiconductor layers 202. The first source/drain epitaxy structures 320 are connected to and in contact with the semiconductor layers 102. In other words, the first source/drain epitaxy structures 320 can be on opposite ends of each of the semiconductor layers 102 along the X direction.

The dielectric layers 316 are removed via a selective etching process. For example, the selective etching process is performed that selectively etches the dielectric layers 316 over the first source/drain epitaxy structures 320 through the source/drain openings O1, with minimal (or no) etching of the semiconductor layers 202, the spacers 115, and the inner spacers 315. The selective etching process is a dry etching process, a wet etching process, other suitable etching process, or combinations thereof.

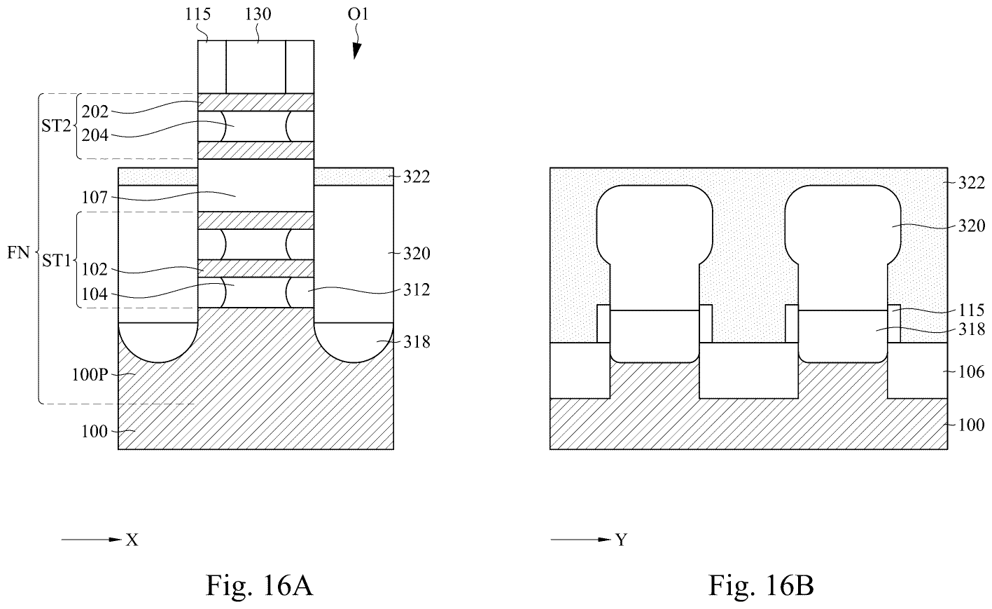

After the removal of the dielectric layers 316, an insulator layer 322 is formed on the top surfaces of the first source/drain epitaxy structures 320 and on the sidewalls of the inners spacers 312, as shown in FIGS. 16A and 16B. In some embodiments, the insulator layer 322 is arranged at two opposite sides of inner spacers 312. In various embodiments, the formation of the insulator layer 322 includes, for example, the deposition and etches. In some embodiments, the insulator layer 322 is made of silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide, which is formed by CVD, including, for example, low pressure CVD (LPCVD) and plasma enhanced CVD (PECVD), physical vapor deposition (PVD), atomic layer deposition (ALD), or other suitable process.

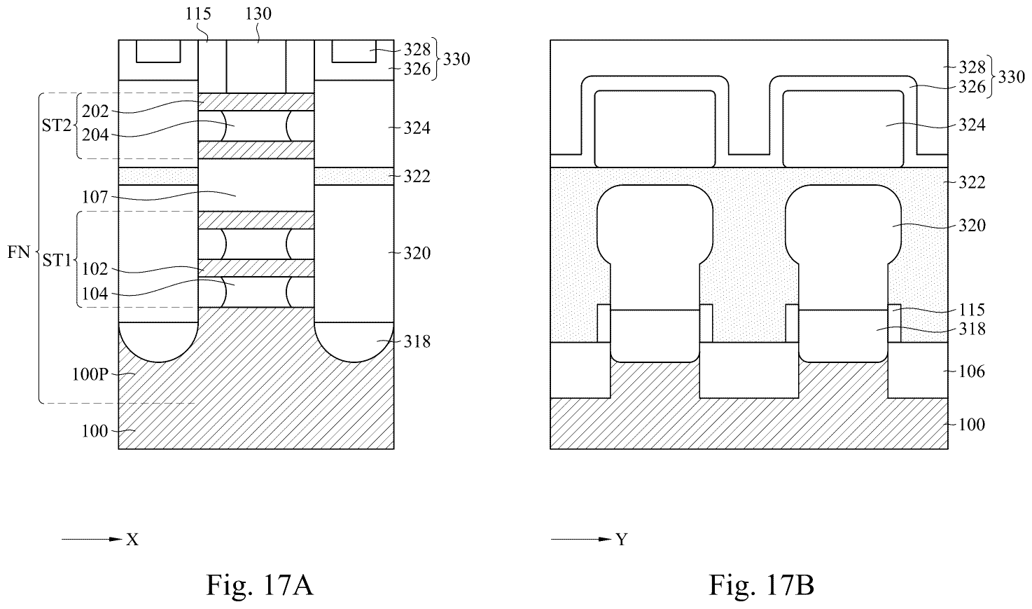

Reference is made to FIGS. 17A and 17B. Second source/drain epitaxy structures 324 are formed on opposite ends of each of the semiconductor layers 202. In some embodiments, the second source/drain epitaxy structures 324 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 324. For example, the implantation process may include p-type dopants, such as boron (B), gallium (Ga), indium (In), aluminium (Al), or the like, such that the second source/drain epitaxy structures 324 are p-type epitaxy structures.

A contact etch stop layer (CESL) 326 is formed covering the second source/drain epitaxy structures 324. Afterwards, an interlayer dielectric (ILD) layer 328 is formed over the CESL 326. Then, a planarization process, such as CMP, is performed to remove excess materials of the CESL 326 and the ILD layer 328 until the dummy gate structures 130 are exposed. In some embodiments, the CESL 326 and the ILD layer 328 can be collectively referred to as an isolation structure 330. In some embodiments, the spacers are in contact with the CESL 155 of the isolation structure 150.

In some embodiments, the CESL 326 may be nitride (such as silicon nitride), and the ILD layer 328 may be oxide (such as silicon oxide). In some embodiments, the CESL 326 may be a dielectric layer including silicon nitride, silicon oxynitride or other suitable materials. In some embodiments, the ILD layer 328 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. The CESL 326 and the ILD layer 328 can be formed using, for example, CVD, ALD or other suitable techniques.

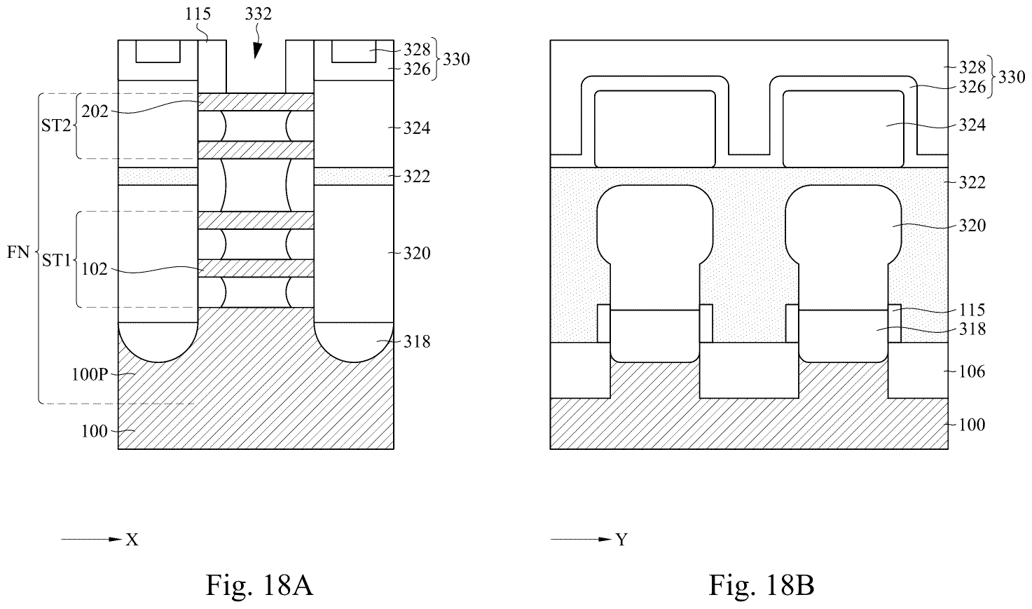

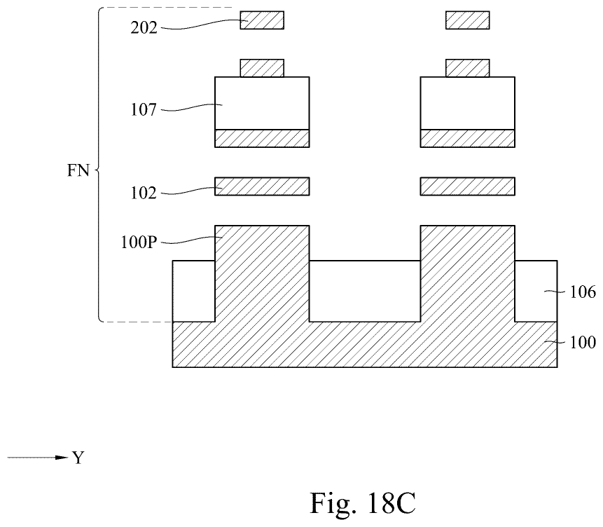

Reference is made to FIGS. 18A, 18B, and 18C. The dummy gate structures 130 are removed to form gate trenches 332 between each pair of the spacers 115. The semiconductor layer 105, the semiconductor layers 204 of the second stack ST2 and the semiconductor layers 104 of the first stack ST1 are removed, such that spaces between two adjacent layers of the semiconductor layers 202 and spaces between two adjacent layers of the semiconductor layers 102 are provided, as shown in FIGS. 18A and 18C. The semiconductor layers 104, 204 are removed or etched using a wet etchant that can selectively etch the semiconductor layers 104, 204, 105 against the semiconductor layers 102, 202. The wet etchant is such as, but not limited to, ammonium hydroxide (NH₄OH), tetramethylammonium hydroxide (TMAH), ethylenediamine pyrocatechol (EDP), or potassium hydroxide (KOH) solution. Alternatively stated, the etching of the semiconductor layers 104, 204, 105 (e.g., SiGe) stops at the semiconductor layers 102, 202.

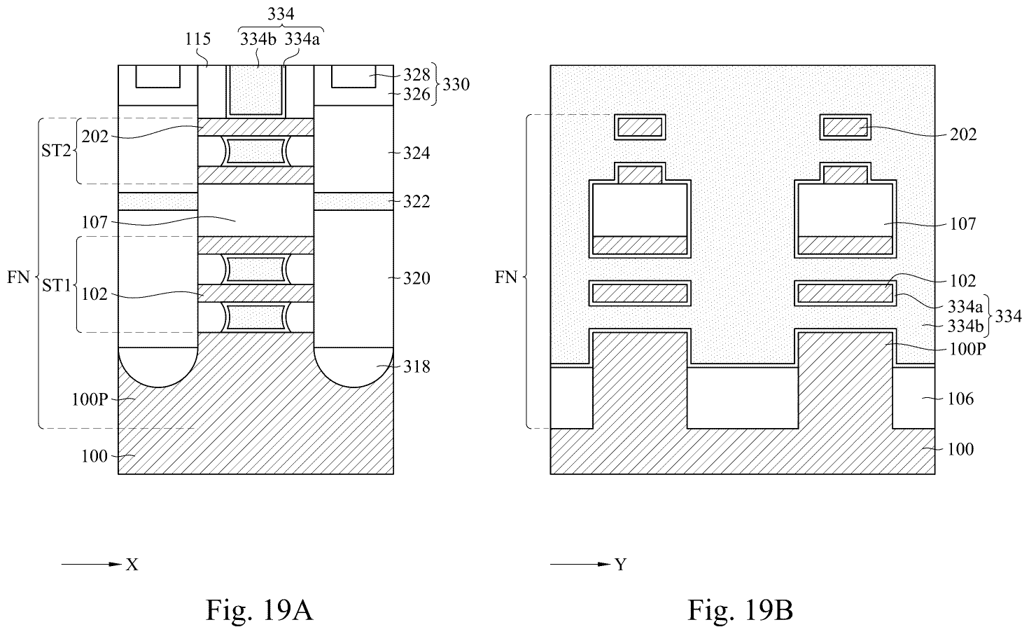

Reference is made to FIGS. 19A and 19B. A first metal gate structure 334 is formed over the semiconductor layers 102, 104 and over the substrate portion 100P. The first metal gate structure 334 can fill in the spaces between the semiconductor layers 102, 202. The first metal gate structure 334 is configured with respect to, for example, the first metal gate structure 170 of FIG. 1. In some embodiments, the first metal gate structure 334 includes an interfacial layer, a gate dielectric layer 334a, one or more layers of gate electrode layer 334b including work function metal layer(s) and a filling metal. The work function metal layer may be an n-type work function layer. Exemplary n-type work function layer can include Ti, Ag, TaAl, TaAlC, TiAlN, TaC, TaCN, TaSiN, Mn, Zr, other suitable n-type work function materials, or combinations thereof. The work function metal layer may include a plurality of layers. The filling metal may include tungsten (W), aluminum (Al), copper (Cu), or another suitable conductive material(s). In some embodiments, the formation of the gate electrode layer 334b layer includes, for example, CVD, ALD, electro-plating, or other suitable method.

In some embodiments, the interfacial layer, the gate dielectric layer 334a, and the gate electrode layer 334b are formed in the spaces between the first semiconductor layers 102 and surrounding the semiconductor layers 102. In some embodiments, the gate dielectric layer 334a includes one or more layers of a dielectric material, such as silicon oxide, silicon nitride, or high-k dielectric material, other suitable dielectric material, and/or combinations thereof. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂-Al₂O₃) alloy, other suitable high-k dielectric materials, and/or combinations thereof. The interfacial layer can be formed between the semiconductor layers 102 and the gate dielectric layer 334a.

In various embodiments, the formation of the gate dielectric layer 334a includes, for example, CVD, ALD or any suitable method. In one embodiment, the gate dielectric layer 334a is formed using a highly conformal deposition process such as ALD in order to ensure the formation of a gate dielectric layer 334a having a uniform thickness around each semiconductor layers 102.

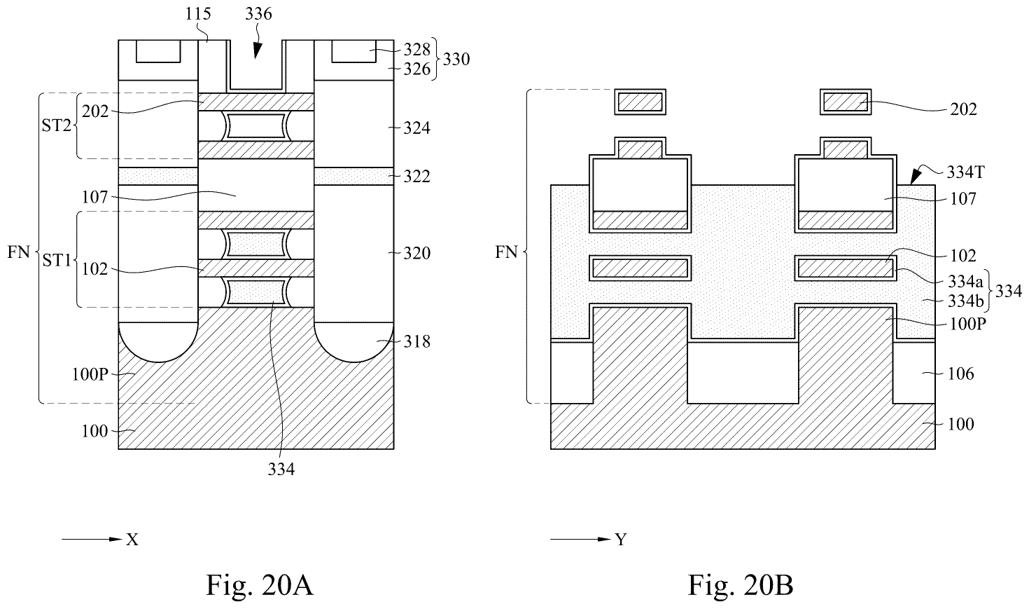

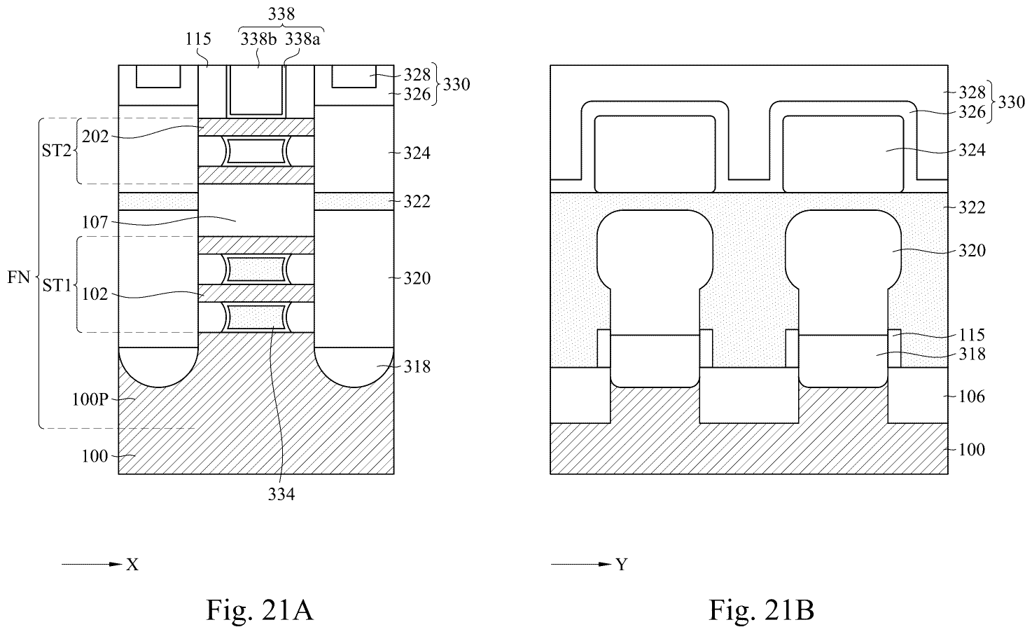

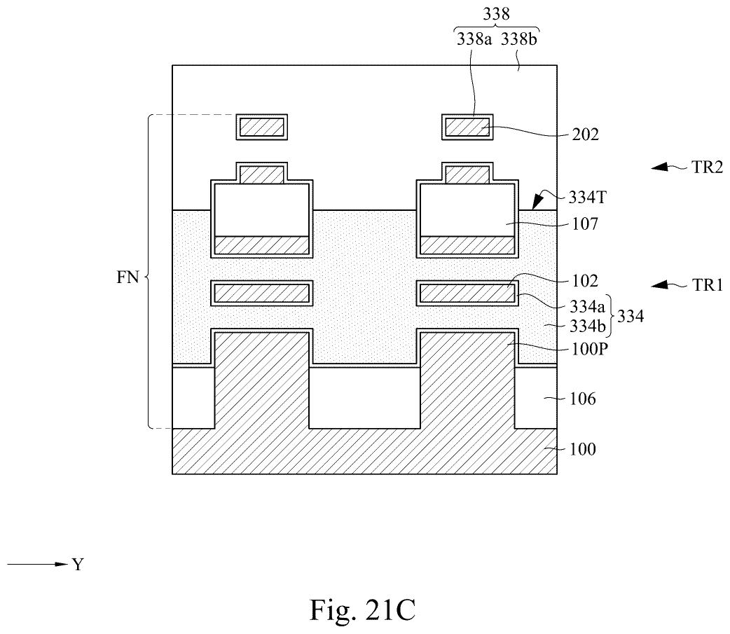

In FIGS. 20A and 20B, the first metal gate structure 334 is recessed to expose the semiconductor layers 202, forming a trench 336 over the first metal gate structure 334. The recess of the first metal gate structure 334 may be performed using a suitable etch-back process, such as dry etch, wet etch, or reactive ion etch (RIE). The etch-back process uses an etchant that selectively removes the first metal gate structure 334 but not the semiconductor layers 202. The etch-back process can include etch back vertically and etch back laterally to recess the first metal gate structure 334. The recessed first metal gate structure 334 has a top surface 334T that may be at a level between the topmost one of the semiconductor layer 102 of the first stack ST1 and the bottom-most one of the semiconductor layers 202 of the second stack ST2. The top surface 334T defines the boundary between the first transistor TR1 and the second transistor TR2 (see FIG. 21C). In FIG. 21C, the MDI structure 107 can interface the first transistor TR1 and the second transistor TR2.

Next, a second metal gate structure 338 is formed in the trench 336, fills in the spaces between the semiconductor layers 202 and over the isolation structure 330. The second metal gate structure 338 is configured with respect to, for example, the second metal gate structure 270 of FIG. 1. In some embodiments, the second metal gate structure 338 includes an interfacial layer, a gate dielectric layer 338a, one or more layers of gate electrode layer 338b including work function metal layer(s) and a filling metal. The work function metal layer may be an p-type work function layer. Exemplary p-type work function layer can include TiN, TaN, TiTaN, TiAlN, WCN, W, Ni, Co, or other suitable material. A planarization process, such as a CMP process, may be performed to remove portions of the second metal gate structure 338 formed over the isolation structure 330 the spacers 115. The resulting structure is shown in FIGS. 21A-21C. In some embodiments, the semiconductor layers 102 can overlap the semiconductor layer 202. The semiconductor layer 102, the first metal gate structure 334 and the first source/drain epitaxy structures 320 can form the first transistor TR1 with respect to FIG. 1. The semiconductor layer 202, the second metal gate structure 338 and the second source/drain epitaxy structures 324 can form the second transistor TR2 with respect to FIG. 1. In some embodiments, the first transistor TR1 and the second transistor TR2 have different conductivity types. In some embodiments, the first transistor TR1 can be a p-type transistor while the second transistor TR2 can be an n-type transistor.

Reference is made to FIGS. 22A-22C. In some embodiments, a dielectric structure 339 can be formed to cut through the first metal gate structure 170 and the second metal gate structure 270. In some embodiments, the dielectric structure can also cut through the isolation structures 106. In some embodiments, the dielectric structure 339 can be referred to as a cut-metal-gate (CMG) isolation structure and can be made of nitride, silicon nitride, oxide, silicon oxide, a combination thereof, or other suitable dielectric material. Formation of the dielectric structure 339 can include etching the first metal gate structure 170 and the second metal gate structure 270 and the isolation structures 106 to form an opening, depositing a dielectric material in the opening, and then performing a planarization process (such as CMP) to remove excess materials of the dielectric material. After forming the second metal gate structure 338, openings may be formed in the ILD layer 328 of the isolation structure 330 to expose the second source/drain epitaxy structures 324, and a conductive layer MD may be formed in each opening over the second source/drain epitaxy structures 324. A silicide layer (not shown) may be formed between the second source/drain epitaxy structures 324 and the conductive layer MD. The conductive layer MD may include a material having one or more of Ru, Mo, Co, Ni. W, Ti, Ta, Cu, Al, TiN and TaN, and may be formed by any suitable process, such as PVD, electro-chemical plating (ECP), or CVD. Additional layers or structures may be formed on the CFET 10 before flipping over to perform back side processes on the CFET 10. In some embodiments, the conductive layer MD can be located at a layer between a first metal layer (not shown) and a layer containing a buried power rail (not shown), and a power pad (not shown) can be coupled to the conductive layer MD through a via.

In some embodiments, after flipping over the CFET 10, the substrate 100 is removed by any suitable method. A dielectric material 342 may be formed over the substrate portion 100P and the isolation structures 106. Openings may be formed in the dielectric material 342, the substrate portion 100P and the insulator layer 318, and a conductive via VB may be formed in the openings. The conductive via VB may be formed over the first source/drain epitaxy structures 320, and the conductive via VB may include the same material as the conductive layer MD. Silicide layers (not shown) may be formed between the first source/drain epitaxy structures 320 and the conductive via VB. In FIGS. 22A and 22C, the semiconductor layers 102, 202 are spaced apart along the Z direction.

FIG. 22D is a simplified schematic top view of a first cell layout diagram of a semiconductor device 12 in accordance with some embodiments of the present disclosure. FIG. 22D is a top view (plane view) of the semiconductor device 12 in accordance with some embodiments. FIG. 22D further depicts an X direction and a Y direction perpendicular to the X direction. The X direction being depicted as horizontal with respect to the page and the Y direction being depicted as vertical are a non-limiting example for the purpose of illustration. The semiconductor device 12 can include the CFET 10 with respect to FIGS. 22A-22C. For example, FIG. 22C corresponds to a cross-sectional view along line X1-X1′ of FIG. 22D. FIG. 22E is a cross-sectional view along line X2-X2′ of FIG. 22D in accordance with some embodiments.

Reference is made to FIGS. 22C, 22D and 22E. The first cell layout can include a plurality of first conductive patterns 400a, 400b, a plurality of second conductive patterns 402a, 402b, a first active region pattern 406, a second active region pattern 408, continuous poly on diffusion edge (CPODE) patterns 404a, 404b. The CPODE patterns 404a, 404b are strip structures which can be formed by forming a trench by removing a dummy gate structure and a portion of a substrate under the dummy structure using a photolithography process and an etch process, and filling the trench with a dielectric layer or an insulating layer. During the photolithography process, the dummy gate structure corresponding to the CPODE pattern is exposed while the other gate structures or dummy gate structures are covered by a mask layer. In some embodiments, the trench separates the two abutted active regions. In some embodiments, the trench is between two abutted standard cells. The trench extends through at least the abutted two well regions of the two abutted active regions, i.e., a bottom surface of the trench is below a bottom surface of the abutted two well regions. In some embodiments, the CPODE patterns 404a, 404b can include SiN, SiO₂, SiON, SiCN, SiCON, SiCO, high-k material (such as HfO, AlO) or multiple layers thereof.

In some embodiments, the first cell layout can include padding cells 410a, 410b. The padding cells 410a, 410b may be provided as the modified cell such that the padding cells 410a, 410b further include a dummy gate line 412 that is not included in its corresponding standard cell. The padding cells 410a, 410b are used to apply a keepout margin around standard cells. When a cell has a high number of pins like a multibit flop, the demand for routing resources increases. Hence, the placement of cells near these cells are restricted to avoid congestion.

The second active region pattern 408 can include the semiconductor layers 102, 104. As discussed previously with respect to FIGS. 6A and 6B, the semiconductor layer 102 has the width W1 different from the width W2a of the semiconductor layer 202a. For example, the width W2a of the semiconductor layer 202 can be smaller than the width W1 of the semiconductor layer 102. For example, the width difference (W1-W2) can be in a range from about 2 nm to about 10 nm. In this case, the substrate portion 100P can have a width W0 along the Y direction substantially the same as the width W1 of the semiconductor layer 102 and greater than the width W2 of the semiconductor layer 202. That is, a width difference (W0-W2) is greater than a width difference (W0-W1). In some embodiments, the width W2a of the semiconductor layer 202 can be in a range from about 5 nm to about 30 nm. In some embodiments, the width W1 of the semiconductor layer 102 can be in a range from about 15 nm to about 80 nm. In some embodiments, a ratio of the width W2a to the width W1 can be in a range from about 0.25 to about 0.8.

In some embodiments, the first semiconductor layer 102 has a width HW1 along the X direction substantially the same as a width HW2 of the second semiconductor layer 202 along the X direction. Therefore, a width difference (HW1-HW2) of the width HW1 and the width HW2 can be different from (e.g., smaller than) the width difference (W1-W2).

In some embodiments, a sheet number of the semiconductor layer 102 can be different from a sheet number of the semiconductor layer 202. In some embodiments, a sheet height H1 of the semiconductor layer 102 can be different from a sheet height H2 of the semiconductor layer 202, and the difference (H1-H2) can be in a range from about 0.5 nm to about 5 nm. In some embodiments, a sheet space S1 of the semiconductor layer 102 can be different from a sheet space S2 of the semiconductor layer 202, and the difference (S1-S2) can be in a range from about 0.5 nm to about 5 nm. In some cases, the semiconductor layer 102 and the semiconductor layer 202 can include different materials. In some embodiments, a thickness T1 of the inner spacers 312 in which the first metal gate structure 334 is sandwiched therebetween can be different from a thickness T2 of the second metal gate structure 338 is sandwiched therebetween, and the difference (T1-T2) can be in a range from about 0.5 nm to about 5 nm.

In some embodiments, in the first active region pattern 406, third transistors TR3 and fourth transistors TR4 are formed. The third transistor TR1 and the fourth transistor TR4 can be similar to the first transistor TR1 and the second transistor TR2, except for the width difference (W3-W4) between the semiconductor layer 102a of the third transistor TR3 and the semiconductor layer 202a of the fourth transistor TR4 being different from the width difference (W1-W2) between the semiconductor layer 102 of the first transistor TR1 and the semiconductor layer 202 of the second transistor TR4. For example, the width difference (W3-W4) between the semiconductor layer 102a of the third transistor TR3 and the semiconductor layer 202a of the fourth transistor TR4 is substantially zero. That is, the width W3 can be substantially the same as the width W4. As a result, the width difference (W3-W4) can be smaller than the width difference (W1-W2).

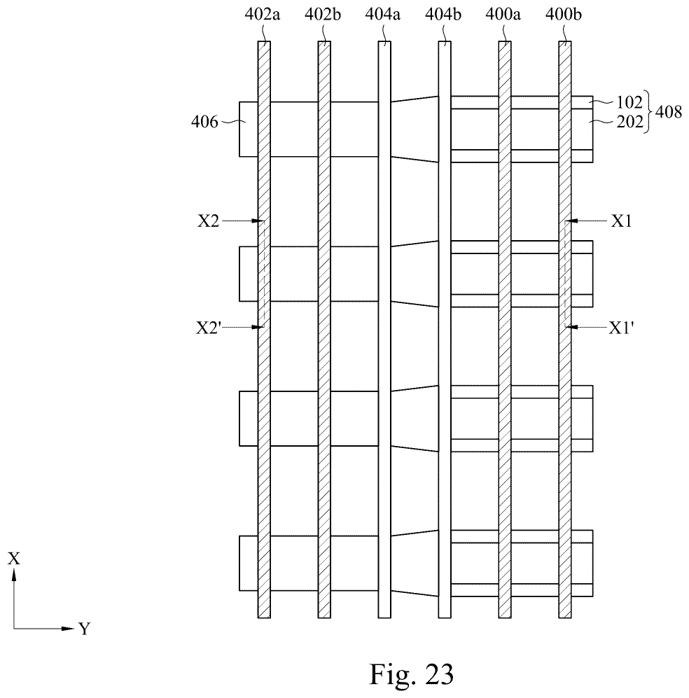

FIG. 23 is a simplified schematic top view of a second cell layout diagram of a semiconductor device in accordance with some embodiments of the present disclosure. The second cell layout is similar to the first cell layout, except for the second cell layout including a width of 1CPP transition with two CPODEs between the first active region pattern 406 and the second active region pattern 408. For example, FIG. 22C corresponds to a cross-sectional view along line X1-X1′ of FIG. 23. FIG. 22E is a cross-sectional view along line X2-X2′ of FIG. 23. In some embodiments, CPP is an abbreviation of the term ‘contact poly pitch.’ In some embodiments, CPP is a minimum center-to-center space (distance) between gates of adjacent transistors of one or more cell structures that are coupled to a single Through Silicon Via (TSV) structure.

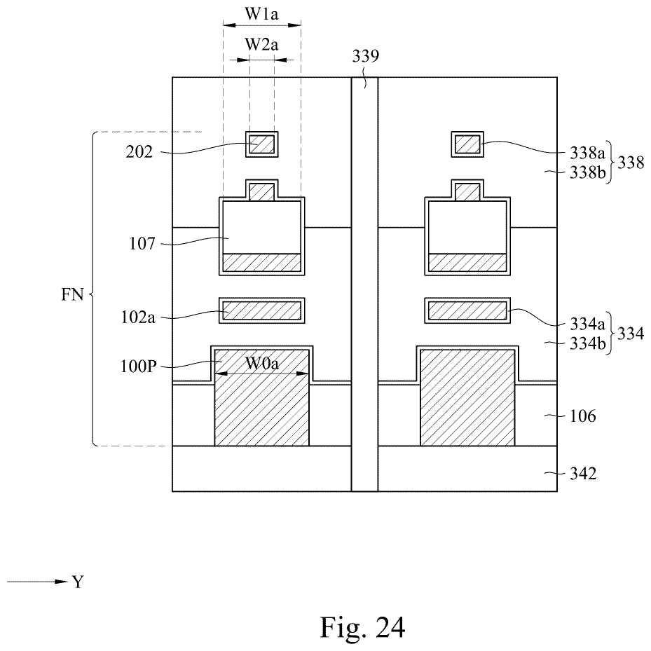

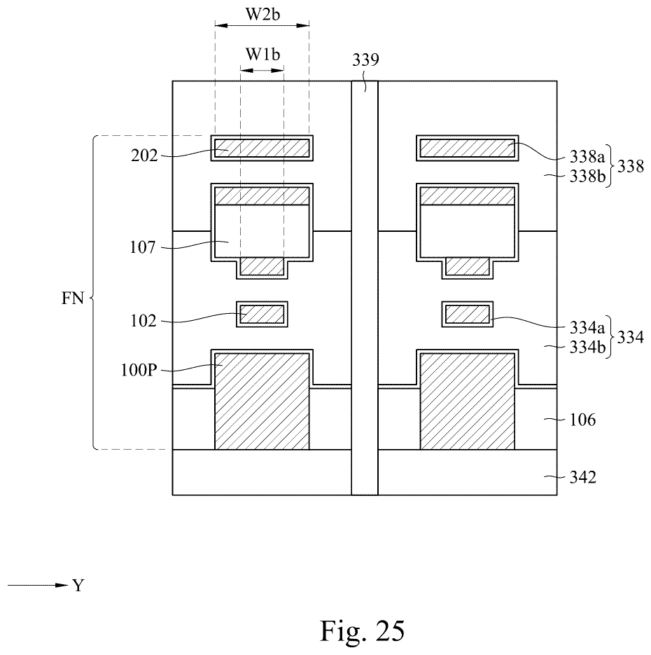

FIG. 24 is a cross-sectional view of the CFET 10 along line B-B of FIG. 1, which is similar to the cross-sectional view with respect to FIG. 22C, except for the substrate portion 100P having the width W0a different from both of the width W1a of the semiconductor layer 102 and the width W2a of the semiconductor layer 202. For example, the substrate portion 100P includes the width W0a greater than the width W1a of the semiconductor layers 102 and the width W2a of the semiconductor layers 202. FIG. 25 is a cross-sectional view of the CFET 10 along line B-B of FIG. 1 similar to the cross-sectional view with respect to FIG. 22C, except for the width W2b of the semiconductor layer 202 being greater than the width w1b of the semiconductor layer 102. In some embodiments, the width W2a of the semiconductor layer 202 can be in a range from about 5 nm to about 30 nm. In some embodiments, the width W1a of the semiconductor layer 102 can be in a range from about 15 nm to about 70 nm. In some embodiments, a ratio of the width W2a to the width W1a can be in a range from about 0.25 to about 0.8.

FIG. 25 is a cross-sectional view of the CFET 10 along line B-B of FIG. 1, which is similar to the cross-sectional view with respect to FIG. 22C, except for the semiconductor layers 202, which are disposed above the semiconductor layers 102, including a width W2b greater than a width W1b of the semiconductor layers 102.

The present disclosure will be described with respect to embodiments in a specific context, a static random-access memory (SRAM) formed with a gate-all-around (GAA) configuration. The embodiments of the disclosure may also be applied, however, to a variety of semiconductor devices. Various embodiments will be explained in detail with reference to the accompanying drawings.

Static random-access memory (SRAM) is a type of volatile semiconductor memory that uses bistable latching circuitry to store bits. Bit in an SRAM is stored on four transistors (PU-1, PU-2, PD-1, and PD-2) that form two cross-coupled inverters. This memory cell has two stable states which are used to denote 0 and 1. Two additional access transistors (PG-1 and PG-2) are electrically connected to the two cross-coupled inventers and serve to control the access to a storage cell during read and write operations.

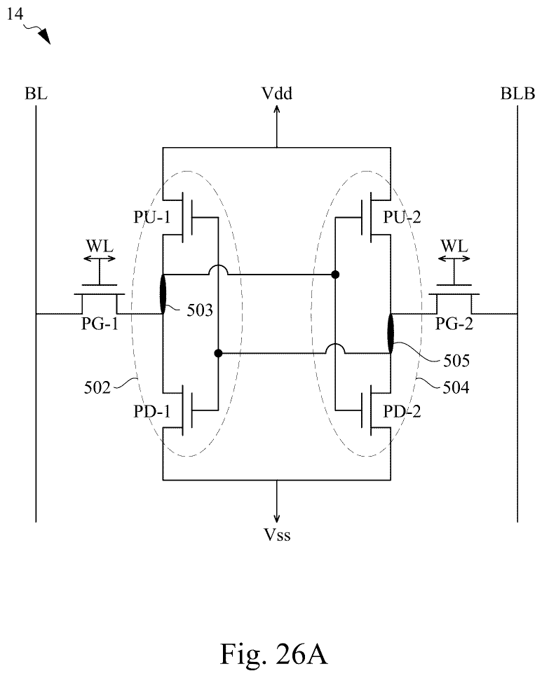

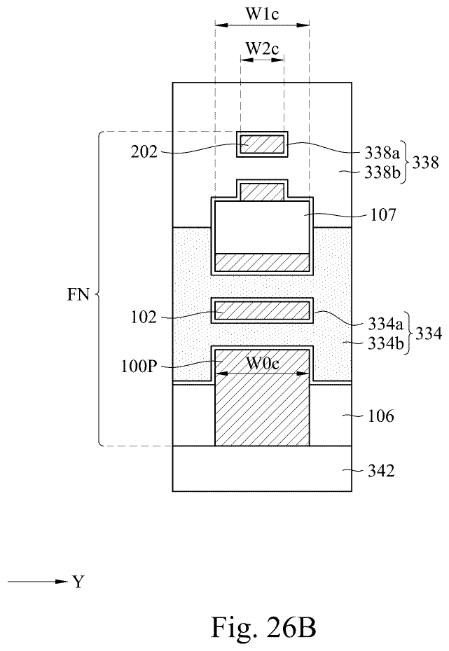

FIG. 26A is a circuit diagram of a six transistor (6T) SRAM cell 14. The SRAM cell 14 includes a first inverter 502 formed by a pull-up transistor PU-1 and a pull-down transistor PD-1. The SRAM cell 14 further includes a second inverter 504 formed by a pull-up transistor PU-2 and a pull-down transistor PD-2. Furthermore, both the first inverter 502 and second inverter 504 are coupled between a power routing Vdd and a power routing Vss. In some embodiments, the power routing Vss may be ground potential. In some embodiment, the pull-up transistor PU-1 and PU-2 can be p-type transistors while the pull-down transistors PD-1 and PD-2 can be n-type transistors, and the claimed scope of the present disclosure is not limited in this respect.

In FIG. 26A, the first inverter 502a nd the second inverter 504 are cross-coupled. That is, the first inverter 502 has an input connected to the output of the second inverter 504. Likewise, the second inverter 504 has an input connected to the output of the first inverter 502. The output of the first inverter 502 is referred to as a storage node 503. Likewise, the output of the second inverter 504 is referred to as a storage node 505. In a normal operating mode, the storage node 503 is in the opposite logic state as the storage node 505. By employing the two cross-coupled inverters, the SRAM cell 14 can hold the data using a latched structure so that the stored data will not be lost without applying a refresh cycle as long as power is supplied through Vdd.

In an SRAM device using the 6T SRAM cells, the cells are arranged in rows and columns. The columns of the SRAM array are formed by a bit line pairs, namely a first bit line BL and a second bit line BLB. The cells of the SRAM device are disposed between the respective bit line pairs. As shown in FIG. 26A, the SRAM cell 14 is placed between the bit line BL and the bit line BLB.

In FIG. 26A, the SRAM cell 14 further includes a first pass-gate transistor PG-1 connected between the bit line BL and the output 503 of the first inverter 502. The SRAM cell 14 further includes a second pass-gate transistor PG-2 connected between the bit line BLB and the output of the second inverter 504. The gates of the first pass-gate transistor PG-1 and the second pass-gate transistor PG-2 are connected to a word line WL, which connects SRAM cells in a row of the SRAM array.

In operation, if the pass-gate transistors PG-1 and PG-2 are inactive, the SRAM cell 14 will maintain the complementary values at storage nodes 503 and 505 indefinitely as long as power is provided through Vdd. This is so because each inverter of the pair of cross coupled inverters drives the input of the other, thereby maintaining the voltages at the storage nodes. This situation will remain stable until the power is removed from the SRAM, or, a write cycle is performed changing the stored data at the storage nodes.

In the circuit diagram of FIG. 26A, the pull-up transistors PU-1, PU-2 are p-type transistors. The pull-down transistors PD-1, PD-2, and the pass-gate transistors PG-1, PG-2 are n-type transistors. In some other embodiments, however, the pull-up transistors PU-1, PU-2 are n-type transistors, and the pull-down transistors PD-1, PD-2, and the pass-gate transistors PG-1, PG-2 are p-type transistors.

The structure of the SRAM cell 14 in FIG. 26A is described in the context of the 6T-SRAM. One of ordinary skill in the art, however, should understand that features of the various embodiments described herein may be used for forming other types of devices, such as an 8T-SRAM memory device, or memory devices other than SRAMs, such as standard cell, gated diode or ESD (Electrostatic Discharge) devices. Furthermore, embodiments of the present disclosure may be used as stand-alone memory devices, memory devices integrated with other integrated circuitry, or the like.

In various embodiments, the PG-1, PG-2, PD-1, PD-2, PU-1, and PU-2 transistors are formed with a gate-all-around (GAA) configuration. That is, the channel regions of each of the PG-1, PG-2, PD-1, PD-2, PU-1, and PU-2 transistors may include a plurality of semiconductor channel layers stacked along a vertical direction, and each of the semiconductor channel layers is wrapped around by a respective gate structure. FIG. 26B shows an exemplary cross-sectional view of the first inverter 502 in accordance with some embodiments. Reference is made to FIGS. 26A and 26B. For example, the first inverter 502 can be formed with a CFET configuration similar to the CFET 10 with respect to FIGS. 22A-22C. For example, the PD-1 transistor and the PU-1 transistor can be similar to the first transistor TR1 and the second transistor TR2, respectively with respect to FIG. 1. That is, the PD-1 transistor can include the semiconductor layers 102 has a lengthwise direction extending along the Y-direction and spaced apart along the Z direction. The PU1 transistor can include the semiconductor layers 202 has a lengthwise direction extending along the Y-direction and spaced apart along the Z direction. The PD-1 transistor of the SRAM cell 14 can also include the first metal gate metal structure 334 wrapping around the semiconductor layers 102. The PU-1 transistor of the SRAM cell 14 can also include the second metal gate structure 338 wrapping around the semiconductor layers 202. The PU-1 transistor can be an NFET, and the PD-1 transistor can be a PFET.

In some embodiments, the substrate portion 100P can have a width W0c different from a width W1c of the semiconductor layers 102 and a width W2c of the semiconductor layers 202. For example, the width W0c is greater than the width W1c and the width W2c. The PU-1 transistor can include semiconductor layers 202 with the width W2c different from (e.g., smaller than) the width W1c of the semiconductor layers 102 of the PD-1 transistor to modulate direct current (DC) for the PU-1 transistor and the PD-1 transistor. Therefore, Logic Design Technology Co-Optimization (DTCO) can be enabled and read/write margin for the SRAM cell 14 can be improved. In some embodiments, the second inverter 504 can include a structure similar to the structure of the first inverter 502.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a CFET with a gate-all-around configuration which includes a first GAA device with a first conductivity-type and a second GAA device with a second conductivity-type different from the first conductivity-type. The first GAA device can include nanosheets with a width different from a width of nanosheets of the second GAA device to modulate direct current (DC) for the first GAA device and the second GAA device. Therefore, Logic Design Technology Co-Optimization (DTCO) can be enabled and read/write margin for static random access memory (SRAM) can be improved.

In some embodiments, a semiconductor device comprises a first transistor and a second transistor on the first transistor. The first transistor comprises a plurality of first semiconductor layers spaced apart from each other along a first direction and a first gate structure around the plurality of first semiconductor layers. One of the plurality of first semiconductor layers has a first width along a second direction perpendicular to the first direction. The second transistor comprises a plurality of second semiconductor layers spaced apart from each other along the first direction and a second gate structure around the plurality of second semiconductor layers. One of the plurality of second semiconductor layers has a second width along the second direction, and a ratio of the second width to the first width or a ratio of the first width to the second width is in a range from about 0.25 to about 0.8. In some embodiments, the second width is smaller than the first width. In some embodiments, the second width is greater than the first width. In some embodiments, the semiconductor device further comprises a semiconductor substrate below the first transistor and the second transistor and an isolation structure surrounding a portion of the semiconductor substrate. The portion of the semiconductor substrate has a third width different from the first width. In some embodiments, the third width is greater than the first width. In some embodiments, the third width is different from the second width. In some embodiments, the third width is greater than the second width. In some embodiments, the first transistor further comprises first source/drain epitaxy structures on opposite ends of each of the plurality of first semiconductor layers along a third direction perpendicular to the second direction. In some embodiments, the first transistor and the second transistor have different conductivity types.

In some embodiments, a semiconductor device comprises a static random access memory (SRAM) cell. The SRAM cell comprises a pull-down transistor and a pull-up transistor. The pull-down transistor is over a substrate. The pull-down transistor comprises a plurality of first channel layers. The pull-up transistor is over the substrate. The pull-up transistor comprises a plurality of second channel layers. The plurality of first channel layers and the plurality of second channel layers are stacked along a first direction, one of the plurality of first channel layers comprises a first width along a second direction perpendicular to the first direction, one of the plurality of second channel layers comprises a second width along the second direction, and a ratio of the second width to the first width or a ratio of the first width to the second width is in a range from about 0.25 to about 0.8. In some embodiments, the second width is smaller than the first width. In some embodiments, the one of the plurality of first channel layers has a third width along a third direction perpendicular to the second direction, the one of the plurality of second channel layers has a fourth width along the third direction, and a width difference between the third width and the fourth width is different from a width difference between the first width and the second width. In some embodiments, the width difference between the third width and the fourth width is smaller than the width difference between the first width and the second width. In some embodiments, the substrate has a fifth width along the second direction, and the fifth width of the substrate is substantially the same as the first width. In some embodiments, the fifth width is greater than the second width. In some embodiments, a width difference between the fifth width and the second width is greater than a width difference between the fifth width and the first width.

In some embodiments, a method of forming a semiconductor device comprises the following steps. A semiconductor stack is formed over a substrate. The semiconductor stack comprises a first stack, a semiconductor layer and a second stack stacked in sequence over the substrate, the first stack comprises alternating first semiconductor layers and first sacrificial layers, and the second stack comprises alternating second semiconductor layers and second sacrificial layers. A hard mask is formed over the semiconductor stack. The semiconductor stack and the substrate are patterned using the hard mask as an etch mask. A trimming operation is performed to trim the second stack such that the first stack has a first width different from a second width of the second stack. A ratio of the second width to the first width or a ratio of the first width to the second width is in a range from about 0.25 to about 0.8 The first sacrificial layers are replaced with a first metal gate structure. The second sacrificial layers are replaced with a second metal gate structure. In some embodiments, the method further comprises prior to performing the trimming operation, forming a bottom antireflective coating (BARC) layer around the first stack and a lower portion of the semiconductor layer and exposing an upper portion of the semiconductor layer. In some embodiments, performing the trimming operation comprises trimming an upper portion of the semiconductor layer such that the upper portion of the semiconductor layer is narrower than a lower portion of the semiconductor layer after the trimming operation is complete. In some embodiments, during performing the trimming operation, the hard mask is over the semiconductor stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first transistor, comprising:
a plurality of first semiconductor layers spaced apart from each other along a first direction, wherein one of the plurality of first semiconductor layers has a first width along a second direction perpendicular to the first direction;
a first gate structure around the plurality of first semiconductor layers; and
a second transistor on the first transistor, comprising:
a plurality of second semiconductor layers spaced apart from each other along the first direction, wherein one of the plurality of second semiconductor layers has a second width along the second direction, and a ratio of the second width to the first width or a ratio of the first width to the second width is in a range from about 0.25 to about 0.8; and
a second gate structure around the plurality of second semiconductor layers.

2. The semiconductor device of claim 1, wherein the second width is smaller than the first width.

3. The semiconductor device of claim 1, wherein the second width is greater than the first width.

4. The semiconductor device of claim 1, further comprising:
a semiconductor substrate below the first transistor and the second transistor; and
an isolation structure surrounding a portion of the semiconductor substrate, wherein the portion of the semiconductor substrate has a third width different from the first width.

5. The semiconductor device of claim 4, wherein the third width is greater than the first width.

6. The semiconductor device of claim 4, wherein the third width is different from the second width.

7. The semiconductor device of claim 4, wherein the third width is greater than the second width.

8. The semiconductor device of claim 1, wherein the first transistor further comprises first source/drain epitaxy structures on opposite ends of each of the plurality of first semiconductor layers along a third direction perpendicular to the second direction.

9. The semiconductor device of claim 1, wherein the first transistor and the second transistor have different conductivity types.

10. A semiconductor device, comprising:
a static random access memory (SRAM) cell comprising:
a pull-down transistor over a substrate, wherein the pull-down transistor comprises a plurality of first channel layers; and
a pull-up transistor over the substrate, wherein the pull-up transistor comprises a plurality of second channel layers, and wherein:
the plurality of first channel layers and the plurality of second channel layers are stacked along a first direction, one of the plurality of first channel layers comprises a first width along a second direction perpendicular to the first direction, one of the plurality of second channel layers comprises a second width along the second direction, and a ratio of the second width to the first width or a ratio of the first width to the second width is in a range from about 0.25 to about 0.8.

11. The semiconductor device of claim 10, wherein the second width is smaller than the first width.

12. The semiconductor device of claim 10, wherein the one of the plurality of first channel layers has a third width along a third direction perpendicular to the second direction, the one of the plurality of second channel layers has a fourth width along the third direction, and a width difference between the third width and the fourth width is different from a width difference between the first width and the second width.

13. The semiconductor device of claim 12, wherein the width difference between the third width and the fourth width is smaller than the width difference between the first width and the second width.

14. The semiconductor device of claim 10, wherein the substrate has a fifth width along the second direction, and the fifth width of the substrate is substantially the same as the first width.

15. The semiconductor device of claim 14, wherein the fifth width is greater than the second width.

16. The semiconductor device of claim 14, wherein a width difference between the fifth width and the second width is greater than a width difference between the fifth width and the first width.

17. A method of forming a semiconductor device, comprising:
forming a semiconductor stack over a substrate, wherein the semiconductor stack comprises a first stack, a semiconductor layer and a second stack stacked in sequence over the substrate, the first stack comprises alternating first semiconductor layers and first sacrificial layers, and the second stack comprises alternating second semiconductor layers and second sacrificial layers;
forming a hard mask over the semiconductor stack;
patterning the semiconductor stack and the substrate using the hard mask as an etch mask;
performing a trimming operation to trim the second stack such that the first stack has a first width different from a second width of the second stack, wherein a ratio of the second width to the first width or a ratio of the first width to the second width is in a range from about 0.25 to about 0.8;
replacing the first sacrificial layers with a first metal gate structure; and
replacing the second sacrificial layers with a second metal gate structure.

18. The method of claim 17, further comprising:
prior to performing the trimming operation, forming a bottom antireflective coating (BARC) layer around the first stack and a lower portion of the semiconductor layer and exposing an upper portion of the semiconductor layer.

19. The method of claim 17, wherein performing the trimming operation comprises trimming an upper portion of the semiconductor layer such that the upper portion of the semiconductor layer is narrower than a lower portion of the semiconductor layer after the trimming operation is complete.

20. The method of claim 17, wherein during performing the trimming operation, the hard mask is over the semiconductor stack.
